(19) United States
(12) Patent Application Publication
(10) Pub. No.: US 2026/0123162 A1
(43) Pub. Date: Apr. 30, 2026

(54) DISPLAY DEVICE, MANUFACTURING METHOD OF THE SAME AND ELECTRONIC DEVICE

(71) Applicant: Samsung Display Co., Ltd., Yongin-si (KR)

(72) Inventors: Ki Chang EOM, Yongin-si (KR); Kyung Rock SON, Yongin-si (KR); Hui Won YANG, Yongin-si (KR); Jae Phil LEE, Yongin-si (KR)

(21) Appl. No.: 19/300,109

(22) Filed: Aug. 14, 2025

(30) Foreign Application Priority Data
Oct. 31, 2024 (KR) 10-2024-0152405

(51) Int. Cl. H10H 29/856; H10H 29/01; H10H 29/49

(52) U.S. Cl. CPC H10H 29/856; H10H 29/012; H10H 29/49

(57) ABSTRACT

A display device includes a substrate, a pixel electrode and a common electrode, a first organic layer on the pixel electrode and the common electrode and having a first opening area, a first bottom connection electrode on the first organic layer and electrically connected to the pixel electrode and a second bottom connection electrode on the first organic layer and electrically connected to the common electrode on the first organic layer, a first protective layer covering the first bottom connection electrode and the second bottom connection electrode, a reflective layer on the first protective layer and overlapping a sloped surface of the first organic layer, a second protective layer covering the reflective layer, a second organic layer on the first opening area, a light emitting element on the second organic layer and including a semiconductor stack, and first and second contact electrodes.

### CROSS-REFERENCE TO RELATED APPLICATION

This application claims priority to and the benefit of Korean Patent Application No. 10-2024-0152405, filed on Oct. 31, 2024, in the Korean Intellectual Property Office, the entire disclosure of which is incorporated by reference herein.

### BACKGROUND

### 1. Field

The present disclosure relates to a display device, a method for manufacturing a display device, and an electronic device.

### 2. Description of the Related Art

As the information society develops, the demand for display devices for displaying images is increasing in various forms. The display device may be a flat panel display device such as a liquid crystal display, a field emission display, a light emitting display, and/or the like.

The light emitting display device may include an organic light emitting display device including an organic light emitting diode (OLED) element as a light emitting element, and an ultra-small light emitting display device including a micro light emitting diode element (hereinafter referred to as a micro light emitting element) as a light emitting element. Because the micro light emitting diode element is made of an inorganic material, it has a long lifespan due to less deterioration issues compared to an organic light emitting diode (OLED) element.

Aspects and features of embodiments of the present disclosure are to provide a display device, a method for manufacturing a display device, and an electronic device capable of increasing light emission efficiency.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes a substrate, a pixel electrode and a common electrode, a first organic layer on the pixel electrode and the common electrode and having a first opening area, a first bottom connection electrode on the first organic layer and electrically connected to the pixel electrode and a second bottom connection electrode on the first organic layer and electrically connected to the common electrode on the first organic layer, a first protective layer covering the first bottom connection electrode and the second bottom connection electrode, a reflective layer on the first protective layer and overlapping a sloped surface of the first organic layer, a second protective layer covering the reflective layer, a second organic layer on the first opening area, a light emitting element on the second organic layer and including a semiconductor stack, a first contact electrode, and a second contact electrode and a first upper connection electrode connecting the first contact electrode of the light emitting element and the first bottom connection electrode, and a second upper connection electrode connecting the second contact electrode and the second bottom connection electrode.

According to one or more embodiments, the reflective layer is around the light emitting element.

According to one or more embodiments, one end of the reflective layer is lower than a lower portion of the light emitting element.

According to one or more embodiments, a portion of the reflective layer overlaps the second organic layer.

According to one or more embodiments, an upper portion of the reflective layer is located higher than an active layer of the light emitting element.

According to one or more embodiments, a display device includes a first reflective film on the pixel electrode and a second reflective film on the common electrode.

According to one or more embodiments, the first bottom connection electrode extends from the first organic layer to a top surface of the first reflective film, and wherein the second bottom connection electrode extends from the first organic layer to a top surface of the second reflective film.

According to one or more embodiments, the first protective layer and the second protective layer have a first contact hole exposing the first bottom connection electrode on a top surface of the first organic layer and a second contact hole exposing the second bottom connection electrode on the top surface of the first organic layer, wherein the first upper connection electrode contacts the first bottom connection electrode through the first contact hole, wherein the second upper connection electrode contacts the second bottom connection electrode through the second contact hole.

According to one or more embodiments, the light emitting element further includes: a conductive layer between the second organic layer and the semiconductor stack and a protective film on one surface and side surfaces of the conductive layer and side surfaces of the semiconductor stack, wherein the first contact electrode is on the protective film and is connected to the conductive layer that is exposed and not covered by the protective film, and wherein the second contact electrode is on the protective film and is in a hole penetrating the conductive layer and a portion of the semiconductor stack.

According to one or more embodiments, the semiconductor stack includes a first semiconductor layer, an active layer, and a second semiconductor layer that are sequentially stacked, and wherein the first contact electrode and the second contact electrode are on an entire side surface of the conductive layer and the first semiconductor layer and an entire side surface of the active layer and are on a portion of a side surface of the second semiconductor layer.

According to one or more embodiments, the first contact electrode and the second contact electrode are in contact with the first protective layer.

According to one or more embodiments of the present disclosure, a display device a substrate, a pixel electrode and a common electrode on the substrate, a first reflective film on the pixel electrode and a second reflective film on the common electrode, a first organic layer on the pixel electrode and the common electrode and having a first opening area, a first protective layer on the first organic layer, a reflective layer on the first protective layer and overlapping a sloped surface of the first organic layer, a second protective layer covering the reflective layer, a second organic layer on the first opening area, a light emitting element on the second organic layer and including a semiconductor stack, a first contact electrode, and a second contact electrode and a first upper connection electrode connecting the first contact electrode of the light emitting element and the pixel electrode, and a second upper connection electrode connecting the second contact electrode and the common electrode, wherein a first contact hole penetrates through the first protective layer, the second protective layer, and the first organic layer to the first reflective film on a top surface of the pixel electrode, and a second contact hole penetrates through the first protective layer, the second protective layer, and the first organic layer to the second reflective film on a top surface of the common electrode, wherein the first upper connection electrode contacts the first reflective film through the first contact hole, and the second upper connection electrode contacts the second reflective film through the second contact hole.

According to one or more embodiments of the present disclosure, an electronic device includes: a display device configured to display an image, wherein the display device includes: a substrate, a pixel electrode on the substrate, a first organic layer on the pixel electrode and having a first opening area, a first bottom connection electrode and a second bottom connection electrode on the first organic layer and electrically connected to the pixel electrode, a first protective layer covering the first bottom connection electrode and the second bottom connection electrode, a reflective layer on the first protective layer and overlapping an inclined surface of the first organic layer, a second protective layer covering the reflective layer, a second organic layer on the first opening area, a light emitting element on the second organic layer and including a contact electrode, a first upper connection electrode and a second upper connection electrode connecting a contact electrode of the light emitting element and the first bottom connection electrode and the second bottom connection electrode and a common electrode on the light emitting element.

According to one or more embodiments, a display device includes a reflective film on the pixel electrode.

According to one or more embodiments, the first bottom connection electrode and the second bottom connection electrode extend from the first organic layer to a top surface of the reflective film.

According to one or more embodiments, the first protective layer and the second protective layer have a contact hole exposing the first bottom connection electrode on a top surface of the first organic layer, wherein the first upper connection electrode contacts the first bottom connection electrode through the first contact hole.

According to one or more embodiments of the present disclosure, a method for manufacturing a display device includes forming a pixel electrode and a common electrode on a circuit board, and forming a first reflective film on the pixel electrode and a second reflective film on the common electrode, the forming a first organic layer on the pixel electrode and the common electrode and having a first opening area, the forming a first bottom connection electrode on the first organic layer and electrically connected to the pixel electrode, and a second bottom connection electrode electrically connected to the common electrode on the first organic layer, the forming a first protective layer covering the first bottom connection electrode and the second bottom connection electrode, a reflective layer on the first protective layer and overlapping an inclined surface of the first organic layer, and a second protective layer covering the reflective layer, the forming a second organic layer in the first opening area, and disposing a light emitting element on the second organic layer and the forming a first upper connection electrode connecting a first contact electrode of the light emitting element and the first bottom connection electrode, and a second upper connection electrode connecting the second contact electrode and the second bottom connection electrode.

According to one or more embodiments, in the forming the second protective layer, wherein a contact hole is formed through the first protective layer and the second protective layer to expose the bottom connection electrode.

According to one or more embodiments, in the forming a first upper connection electrode connecting a first contact electrode of the light emitting element and the first bottom connection electrode, and a second upper connection electrode connecting the second contact electrode and the second bottom connection electrode, wherein the first upper connection electrode contacts the first bottom connection electrode through the contact hole.

According to one or more embodiments of the present disclosure, an electronic device includes a display device for displaying an image, wherein the display device includes a substrate, a pixel electrode and a common electrode, a first organic layer on the pixel electrode and the common electrode and having a first opening area, a first bottom connection electrode on the first organic layer and electrically connected to the pixel electrode and a second bottom connection electrode electrically connected to the common electrode on the first organic layer, a first protective layer covering the first bottom connection electrode and the second bottom connection electrode, a reflective layer on the first protective layer and overlapping a sloped surface of the first organic layer, a second protective layer covering the reflective layer, a second organic layer on the first opening area, a light emitting element on the second organic layer and including a semiconductor stack, a first contact electrode, and a second contact electrode and a first upper connection electrode connecting the first contact electrode of the light emitting element and the first bottom connection electrode, and a second upper connection electrode connecting the second contact electrode and the second bottom connection electrode.

According to the display device and the manufacturing method thereof according to embodiments, the light emission efficiency may be increased by reflecting light traveling in a lateral direction due to an organic layer and a reflective layer on the side of the light emitting element.

However, the effects, aspects, and features of the present disclosure are not limited to the aforementioned effects, aspects, and features, and various other effects are included in the present specification.

### DETAILED DESCRIPTION

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit diagram illustrating a sub-pixel according to one or more embodiments.

FIG. 5 is a layout diagram illustrating pixels of a display area according to one or more embodiments.

FIG. 6 is a cross-sectional view illustrating one example of a cross-section of a display panel corresponding to the line I-I′ in FIG. 5.

FIG. 7 is a cross-sectional view illustrating one example of an area A of FIG. 6 in detail.

FIG. 8 is an enlarged view of a portion of FIG. 7

FIG. 9 is a cross-sectional view illustrating another example of the area A of FIG. 6 in detail.

FIG. 10 is a cross-sectional view illustrating another example of the area A of FIG. 6 in detail.

FIG. 11 is an image illustrating a cross-sectional view of a display panel according to one or more embodiments.

FIG. 12 is a layout diagram illustrating pixels of a display area according to one or more embodiments.

FIG. 13 a cross-sectional view illustrating an example of a cross-section of a display panel corresponding to the line I2-I2′ of FIG. 12.

FIG. 14 is a cross-sectional view illustrating an example of an area B of FIG. 13 in detail.

FIG. 15 is a flow chart illustrating a method for manufacturing a display device according to one or more embodiments.

FIG. 16-FIG. 25 are example drawings to illustrate a method for manufacturing a display device according to one or more embodiments.

FIG. 26 is an example view of a smart watch including a display device according to one or more embodiments.

FIGS. 27 and 28 are example views of a virtual reality (VR) device including a display device according to one or more embodiments.

FIG. 29 is an example view of a VR device including a display device according to one or more embodiments.

FIG. 30 is an example view illustrating a vehicle instrument cluster and center fascia including display devices according to one or more embodiments.

FIG. 31 is an example view of a transparent display device including a display device according to one or more embodiments.

### BRIEF DESCRIPTION OF THE DRAWINGS

The aspects and features of the present disclosure, and the methods for achieving them, will become clear with reference to the embodiments described in detail below with the accompanying drawings. However, the present disclosure is not limited to the embodiments disclosed below, but may be implemented in many different forms, and these embodiments are provided only to make the present disclosure complete and to fully inform those skilled in the art of the disclosure of the scope of the disclosure, and the present disclosure may be defined by the scope of the claims and their equivalents.

References to an element or layer as being “on” another element or layer include both cases where the other layer or element is directly on top of or interposed between other elements. The same reference numerals refer to the same components throughout the specification. The shapes, sizes, ratios, angles, numbers, etc. disclosed in the drawings to illustrate the embodiments are examples, and therefore the present disclosure is not limited to the matters illustrated.

Each feature of the various embodiments of the present disclosure may be partially or entirely combined or combined with each other and may be technically capable of various interconnections and operations. Each embodiment may be implemented independently of each other or may be implemented together in a related relationship. Specific embodiments are described below with reference to the attached drawings.

FIG. 1 is a perspective view illustrating a display device according to one or more embodiments.

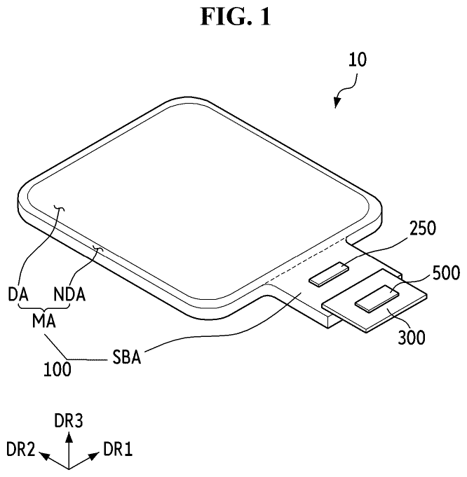

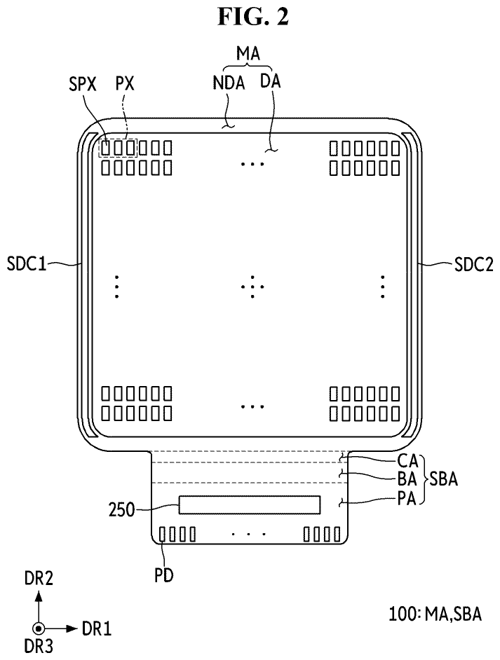

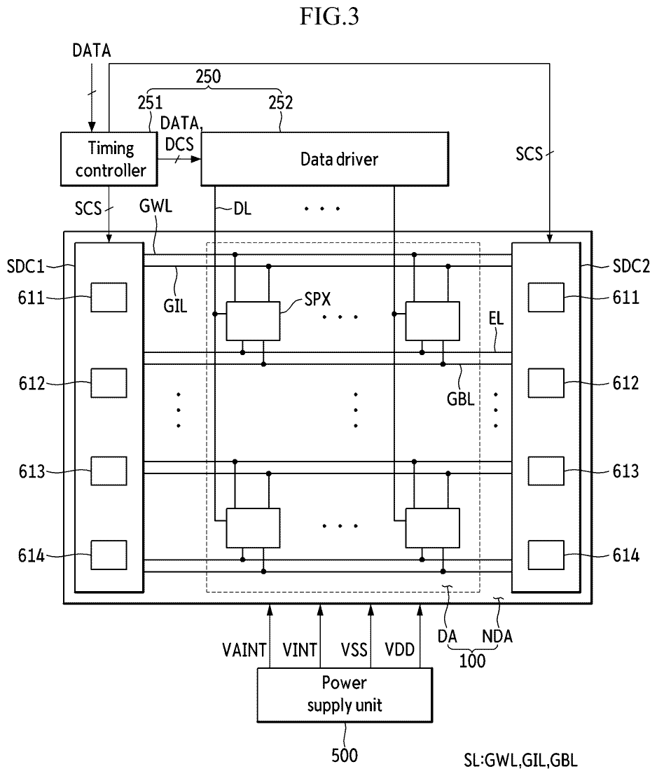

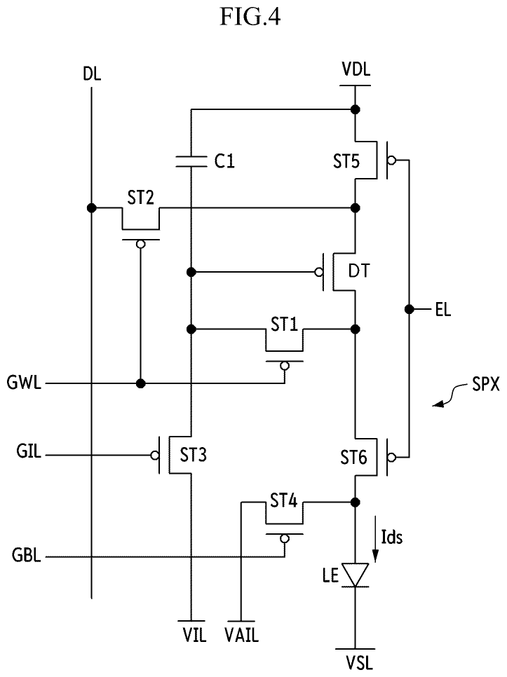

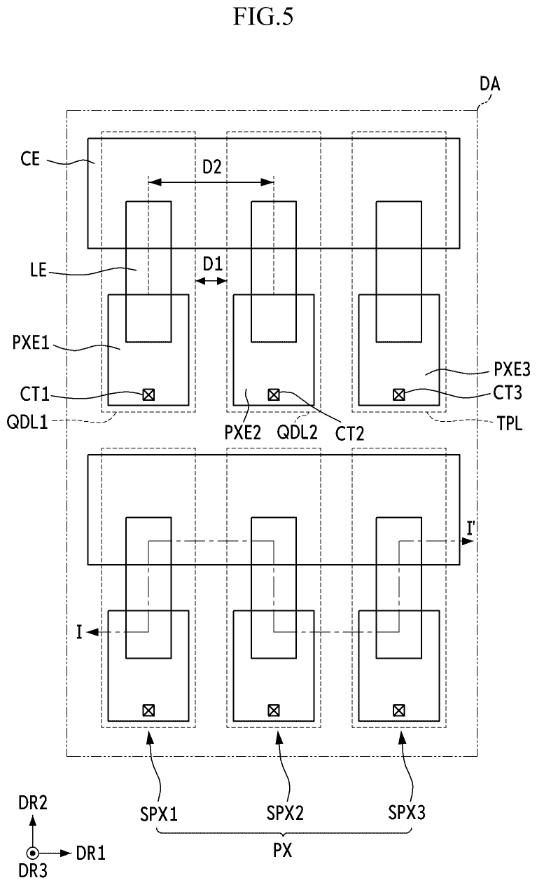

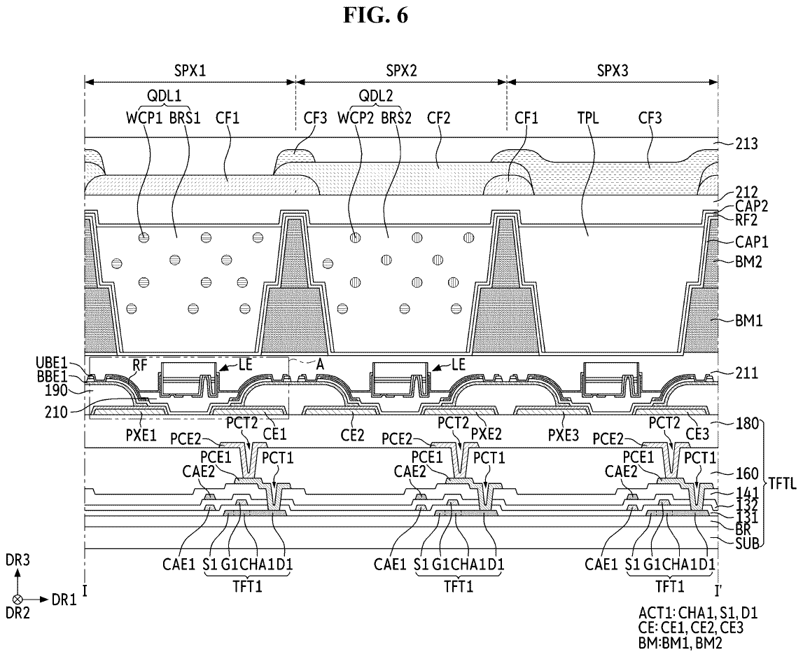

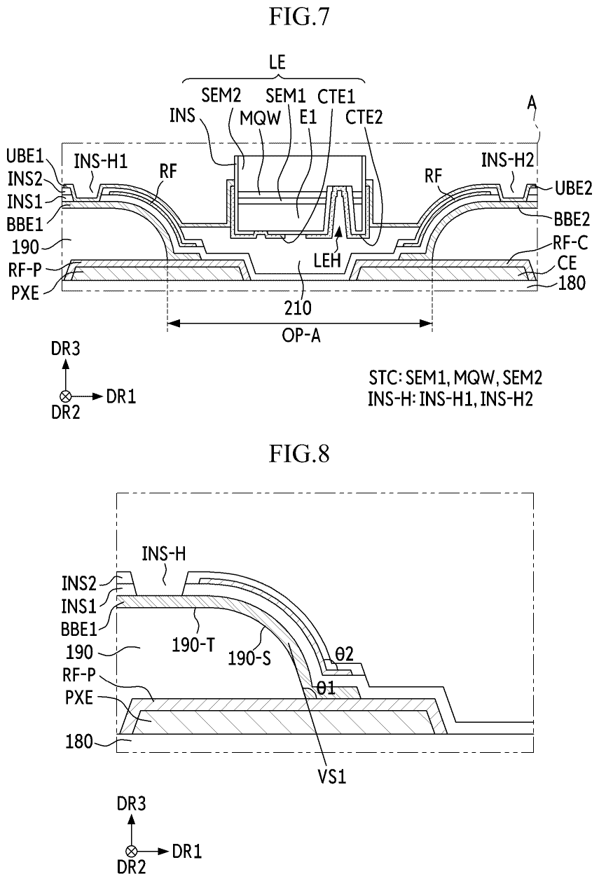

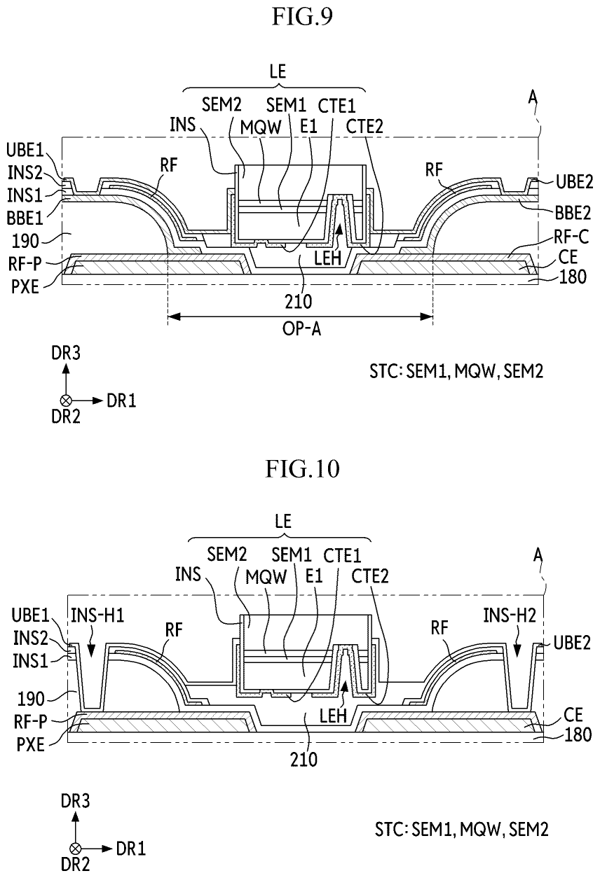

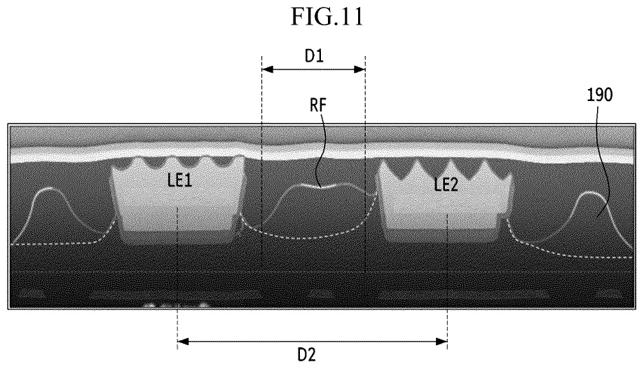

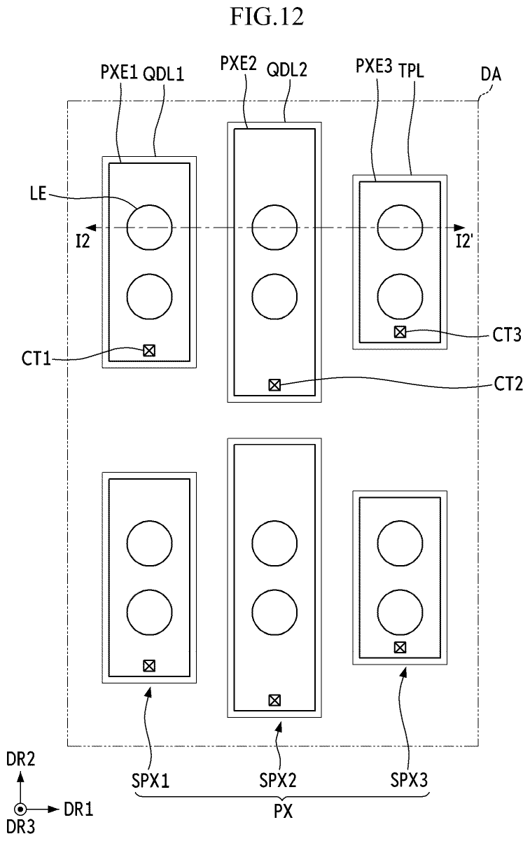

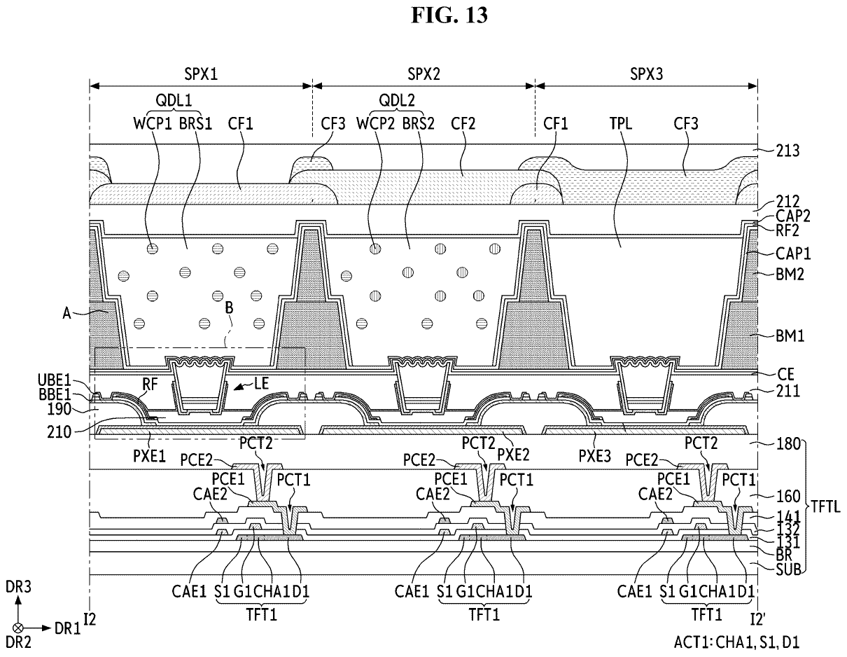

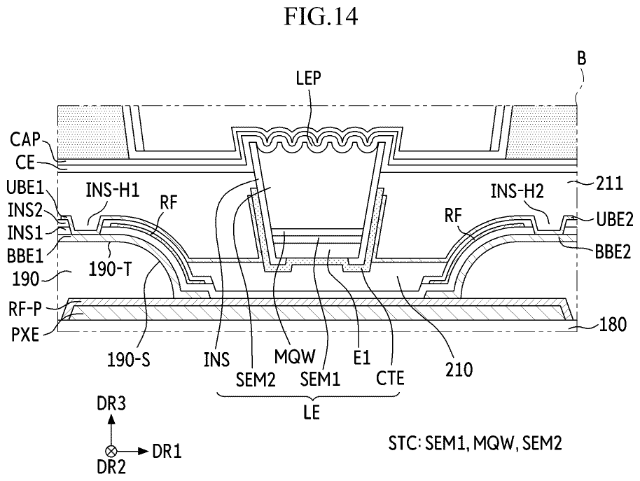

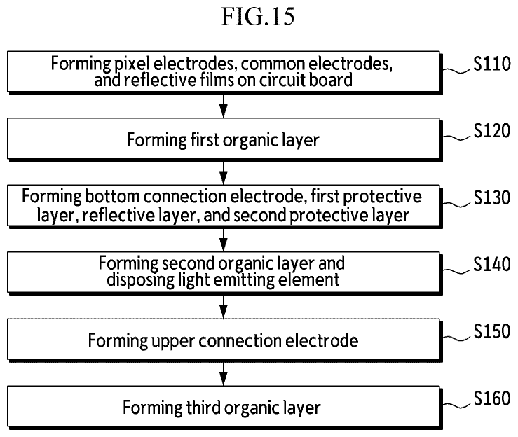

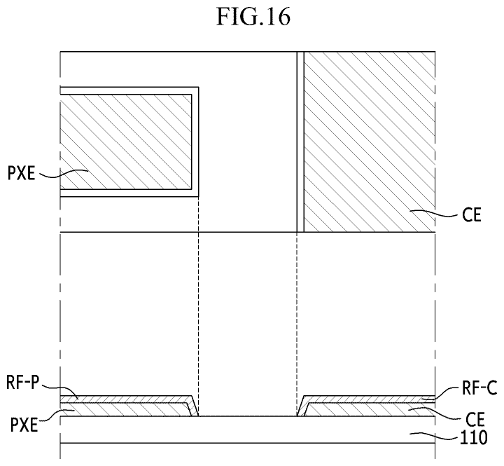

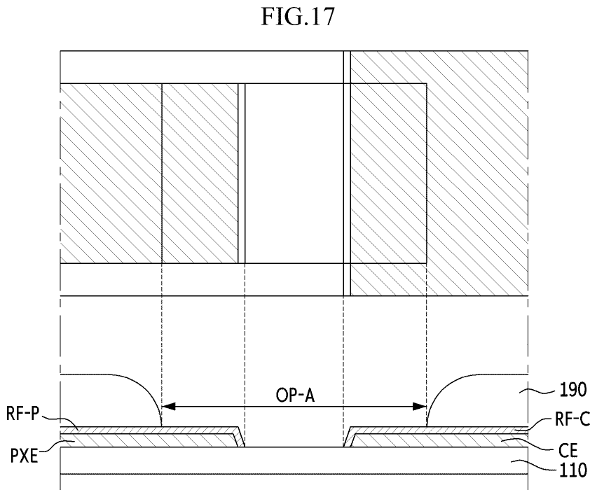

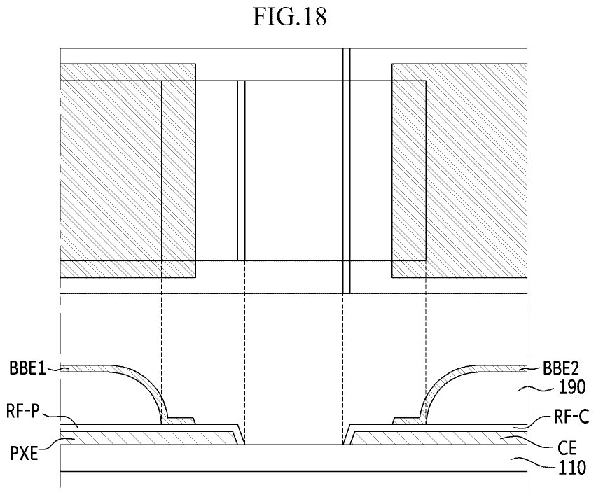

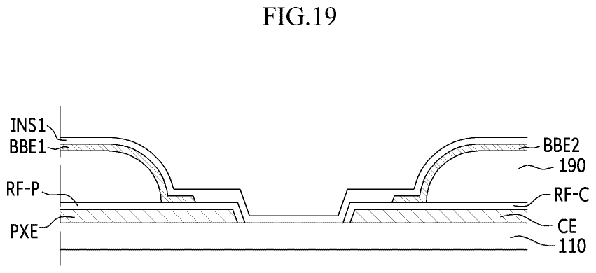

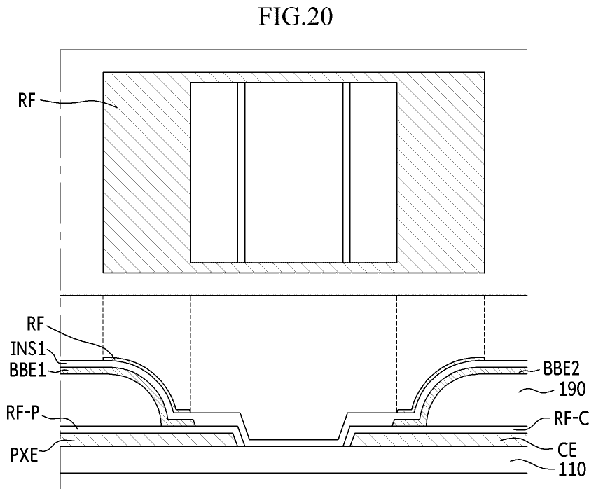

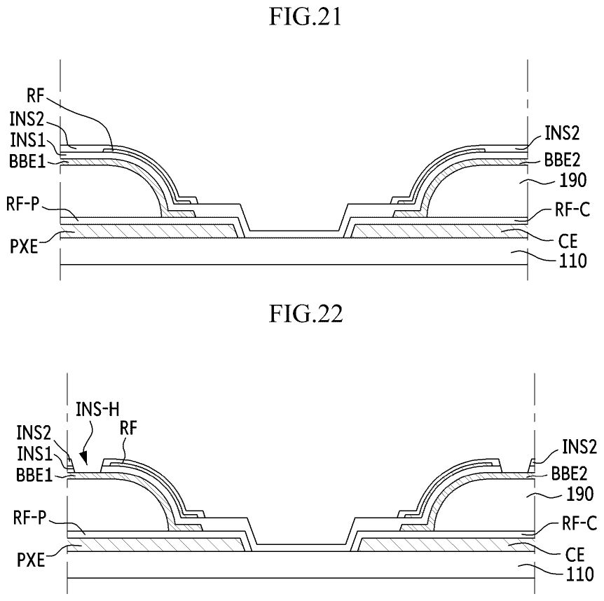

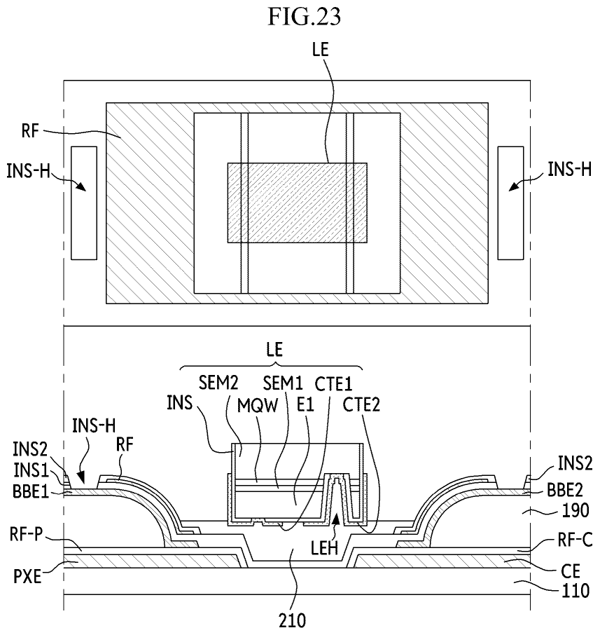

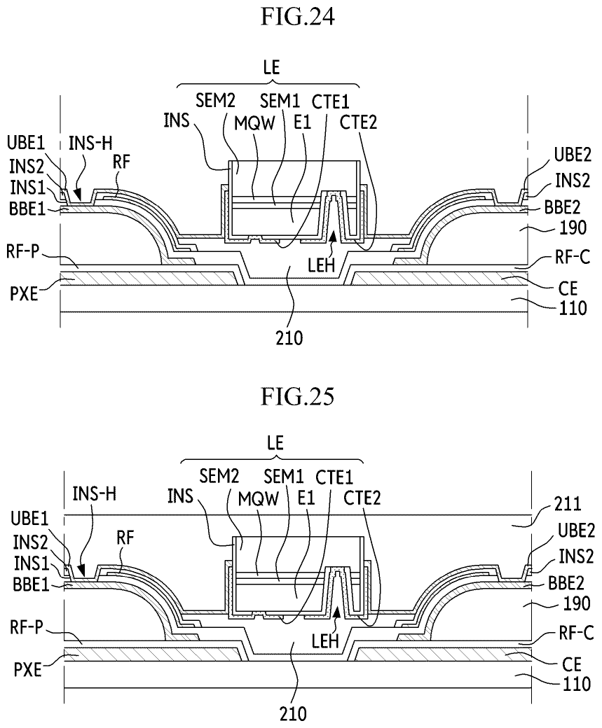

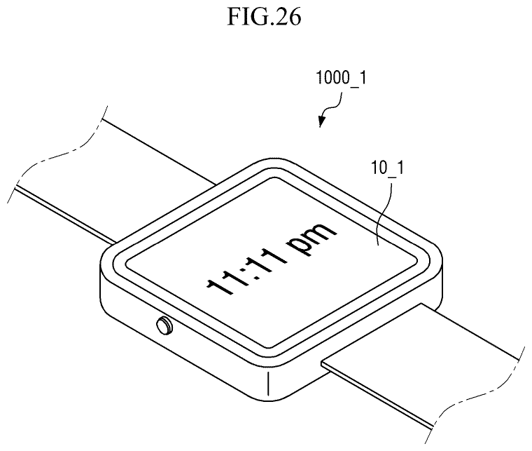

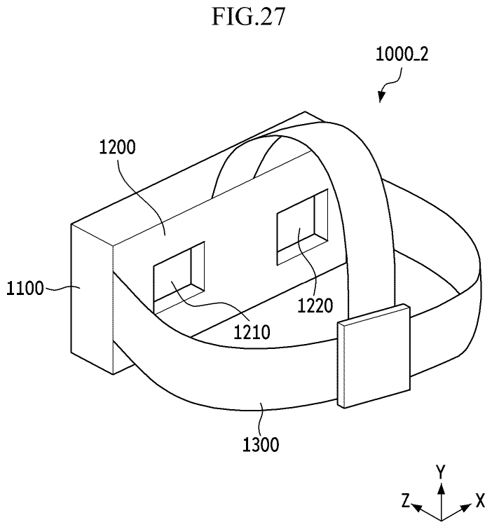

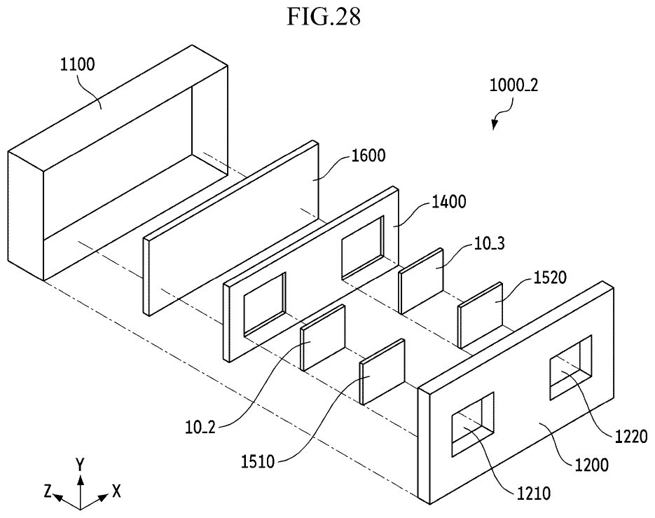

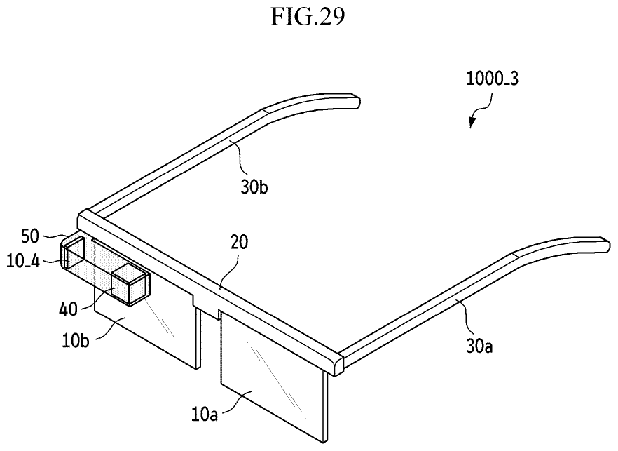

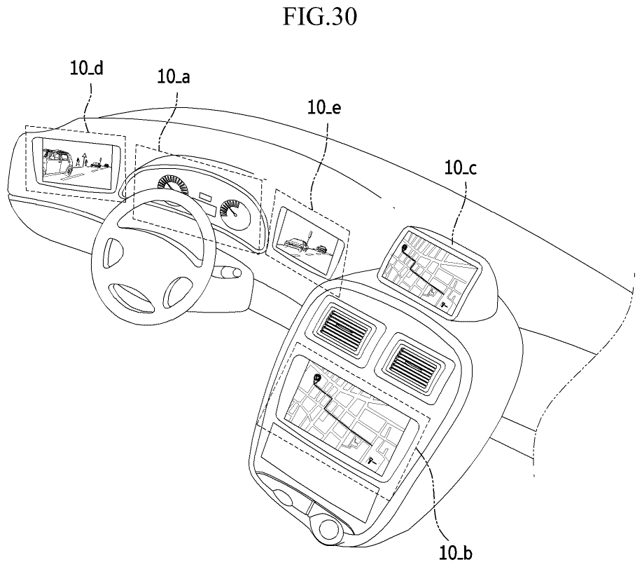

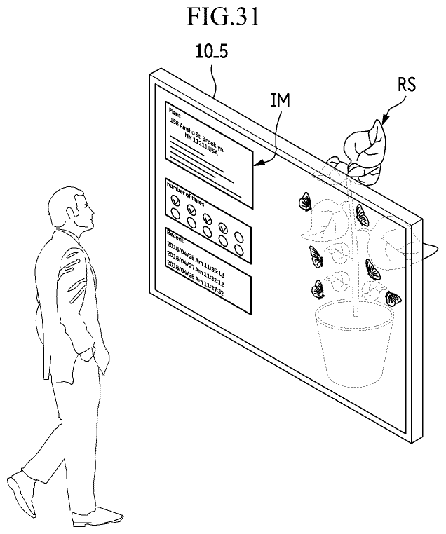

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and/or ultra mobile PC (UMPC), as well as display screens for a variety of products such as televisions, laptops, monitors, billboards, and/or the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation.

The display device 10 includes a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In addition, the display panel 100 may be flexibly formed to be bent, curved, bent, folded, and/or rolled.

The display panel 100 may include the main area MA and the sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits a first light, a second sub-pixel that emits a second light, and a third sub-pixel that emits a third light, but the present disclosure is not limited thereto.

The sub-area SBA may protrude from one side of the main area MA in the second direction DR2. Although FIG. 1 illustrates the sub-area SBA being unfolded, the sub-area SBA may be bent, and in this case, may be disposed on the lower surface of the display panel 100. When the sub-area SBA is bent, it may overlap the main area MA in a third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, and/or an ultrasonic bonding method but is not limited thereto. In one or more embodiments, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, and/or a chip on film.

The power supply circuit 500 may generate a plurality of panel driving voltages according to an external power supply voltage. The power supply circuit 500 may be formed as an integrated circuit (IC) and attached to the circuit substrate 300 using a COF method.

FIG. 2 is a layout drawing illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA and disposed along an edge or a periphery of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be disposed adjacent to the display area DA. The non-display area NDA may be an area outside the display area DA. The non-display area NDA may be arranged to surround the display area DA. The non-display area NDA may be an edge area of the display panel 100.

A first scan driving portion SDC1 and a second scan driving portion SDC2 may be disposed in the non-display area NDA. The first scan driving portion SDC1 is disposed on one side (e.g., the left side) of the display panel 100, and the second scan driving portion SDC2 is disposed on the other side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length of the first direction DR1 of the sub area SBA may be less than the length of the first direction DR1 of the main area MA or may be substantially equal to the length of the first direction DR1 of the main area MA. The sub-area SBA may be curved and may be disposed at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit substrate 300 (e.g., see FIG. 1) may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

FIG. 3 is a block drawing illustrating a display device according to one or more embodiments.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be disposed along the second direction DR2. The plurality of data lines DL may extend in the second direction DR2 and be disposed along the first direction DR1. The plurality of scan lines SL may include a plurality of write scan lines GWL, a plurality of control scan lines, a plurality of initialization scan lines GIL, and a plurality of bias scan lines GBL.

Each of the plurality of sub-pixels SPX may be connected to a write scan line GWL from among the plurality of write scan lines GWL, a control scan line from among the plurality of control scan lines, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light from the light emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251 of the display driving circuit 250.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 includes a timing control circuit 251 and a data driving circuit 252.

The data driving circuit (e.g., the data driver) 252 may receive digital video data DATA and a data timing control signal DCS from the timing control circuit 251.

The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit (e.g., the timing controller) 251 may receive digital video data DATA and timing signals from the outside. The timing control circuit 251 may generate a scan timing control signal SCS and a data timing control signal DCS for controlling the display panel 100 according to the timing signals. The timing control circuit 251 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit (e.g., the power supply unit) 500 may generate a plurality of panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

FIG. 4 is an equivalent circuit drawing illustrating a sub-pixel according to one or more embodiments.

Referring to FIG. 4, a sub-pixel SPX according to one or more embodiments may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The sub-pixel SPX according to one or more embodiments includes a driving transistor DT, switching elements, a capacitor C1, and a light emitting element LE. The switching elements include first to sixth transistors ST1, ST2, ST3, ST4, ST5, and ST6.

The driving transistor DT includes a gate electrode, a first electrode, and a second electrode. The driving transistor DT controls a drain-source current (Ids, hereinafter referred to as “driving current”) flowing between the first electrode and the second electrode of the driving transistor DT according to a data voltage applied to the gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied.

A capacitor C1 is formed between the gate electrode of a driving transistor DT and a first power supply line VDL to which a first power supply voltage is applied. The first power supply voltage may be a voltage of a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, the gate electrode of the fourth transistor ST4 may be connected to the bias scan line GBL, and the gate electrodes of the fifth and sixth transistors ST5 and ST6 may be connected to the emission control line EL. Because the first to sixth transistors ST1, ST2, ST3, ST4, ST5, and ST6 are formed as p-type MOSFET and they may be turned on when a scan signal of a gate low voltage and an emission control signal of a gate low voltage are applied to the initialization scan line GIL, the write scan line GWL, the bias scan line GBL, and the emission control line EL, respectively. One electrode of the third transistor ST3 may be connected to the first initialization voltage line VIL to which the third power supply voltage (VINT of FIG. 3) is applied, and one electrode of the fourth transistor ST4 may be connected to the second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of a p-type MOSFETs are formed of polysilicon, the active layers of each of the first transistor ST1 and the third transistor ST3 formed of an n-type MOSFET may be formed of an oxide semiconductor. Furthermore, because the first transistor ST1 and the third transistor ST3 are formed as an n-type MOSFET, the first transistor ST1 may be turned on when a write scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as a p-type MOSFET, so they may be turned on when a scan signal of the gate low voltage and an emission control signal of the gate low voltage are applied.

Alternatively, the fourth transistor ST4 may be formed as an n-type MOSFET, and the remaining transistors DT, ST1, ST2, ST3, ST5, and ST6 may be formed as a p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on when a scan signal of a gate high voltage is applied, whereas the remaining transistors DT, ST1, ST2, ST3, ST5, and ST6 may be turned on when a scan signal of a gate low voltage and an emission control signal of a gate low voltage are applied.

Alternatively, the first to sixth transistors ST1, ST2, ST3, ST4, ST5, and ST6 and the driving transistor DT may all be formed as an n-type MOSFET. In this case, the active layer of each of the first to sixth transistors ST1, ST2, ST3, ST4, ST5, and ST6 and the driving transistor DT is formed of an oxide semiconductor and may be turned on when a scan signal of a gate high voltage and an emission control signal of a gate high voltage are applied.

FIG. 5 is a layout drawing illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the sub-pixels may be the first sub-pixel SPX1, the second sub-pixel SPX2, and the third sub-pixel SPX3.

The plurality of pixels PX may be disposed in a matrix form. In each of the plurality of pixels PX, the first sub-pixel SPX1, the second sub-pixel SPX2, and the third sub-pixel SPX3 may be disposed along a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a red wavelength band, the second color light may be light in a green wavelength band, and the third color light may be light in a blue wavelength band. For example, the blue wavelength band may refer to light having a main peak wavelength in the wavelength band from approximately 370 [symbol] to 460 [symbol] , the green wavelength band may refer to light having a main peak wavelength in the wavelength band from approximately 480 [symbol] to 560 [symbol] , and the red wavelength band may refer to light having a main peak wavelength in the wavelength band from approximately [symbol] to 750 [symbol] .

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a light emitting element LE, a common electrode CE, and a first light conversion layer QDL1. The second sub-pixel SPX2 includes a second pixel electrode PXE2, a light emitting element LE, a common electrode CE, and a second light conversion layer QDL2. The third sub-pixel SPX3 includes a third pixel electrode PXE3, a light emitting element LE, a common electrode CE, and a light transmission layer TPL.

Each of the pixel electrodes PXE1, PXE2, and PXE3 and the common electrode CE may have a rectangular planar shape, but the present disclosure is not limited thereto.

The areas of the first light conversion layer QDL1, the second light conversion layer QDL2, and the light transmission layer TPL may be the same but are not limited thereto. For example, when the light conversion efficiency of the second light conversion layer QDL2 is lower than the light conversion efficiency of the first light conversion layer QDL1, the area of the second light conversion layer QDL2 may be larger than the area of the first light conversion layer QDL1 and the area of the second pixel electrode PXE2 may be larger than the area of the first pixel electrode PXE1. Furthermore, because the light transmission layer TPL directly transmits the light of the light emitting element LE, while the first light conversion layer QDL1 converts the light, the area of first light conversion layer QDL1 may be larger than the area of the light transmission layer TPL and the area of the first pixel electrode PXE1 may be larger than the area of the third pixel electrode PXE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The common electrode CE may be connected to the second power supply line VSL to which the second driving voltage VSS is applied. Referring to FIG. 5, the common electrode CE may be an electrode commonly disposed in the first sub-pixel SPX1, the second sub-pixel SPX2, and the third sub-pixel SPX3 disposed along the first direction but is not limited thereto. For example, the first common electrode, the second common electrode, and the third common electrode may be disposed in the first sub-pixel SPX1, the second sub-pixel SPX2, and the third sub-pixel SPX3, respectively.

The pixel electrodes PXE1, PXE2, and PXE3 may be referred to as anode electrodes or first electrodes, and the common electrodes CE may be referred to as cathode electrodes or second electrodes.

A plurality of light emitting elements LE may be disposed on the pixel electrodes PXE1, PXE2, and PXE3 and the common electrode CE. Each of the plurality of light emitting elements LE may have a rectangular planar shape, but the present disclosure is not limited thereto. For example, each of the plurality of light emitting elements LE may have a circular planar shape.

The first light conversion layer QDL1 may completely overlap with the plurality of light emitting elements LE of the first sub-pixel SPX1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit the light. For example, the second light conversion layer QDL2 may convert or shift the third light emitted from the plurality of light emitting elements LE of the second sub-pixel SPX2 into the second light.

The light transmission layer TPL may completely overlap the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

When the light emitting element LE of the first sub-pixel SPX1 emits light of a first color, the light emitting element LE of the second sub-pixel SPX2 emits light of a second color, and the light emitting element LE of the third sub-pixel SPX3 emits light of a third color, the light conversion layers QDL1 and QDL2 and the light transmission layer TPL may be omitted.

FIG. 6 is a cross-sectional view illustrating one example of a cross-section of a display panel corresponding to the line I-I′ in FIG. 5. FIG. 7 is a cross-sectional view illustrating one example of an area A of FIG. 6 in detail. FIG. 8 is an enlarged view of a portion of FIG. 7. FIG. 9 is a cross-sectional view illustrating another example of the area A of FIG. 6 in detail.

Referring to FIGS. 6-7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film that protects the transistors of a thin-film transistor layer TFTL from moisture penetrating through the substrate SUB which is vulnerable to moisture permeation. The barrier film BR may be formed of a plurality of inorganic films that are alternately stacked.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and may cover the barrier film BR.

A first gate metal layer may be disposed on the first gate insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being spaced from each other in FIG. 6, the first gate electrode G1 and the first capacitor electrode CAE1 may be connected to each other.

A second gate insulating film 132 may be disposed on the first gate electrode G1 of the thin film transistor TFT1 and the first capacitor electrode CAE1, and may cover the first gate insulating film 131.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and may cover the second gate insulating film 132.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 and may cover the interlayer insulating film 141 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A second planarization organic film 180 may be disposed on the second source connection electrode PCE2 and may cover the first planarization organic film 160.

The barrier film BR, the first gate insulating film 131, the second gate insulating film 132, and the interlayer insulating film 141 may be formed of an inorganic film, for example, silicon nitride (SiNₓ), silicon oxide (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be disposed on the second planarization organic film 180. The light emitting element layer may include pixel electrodes PXE1, PXE2, PXE3, light emitting elements LE, a common electrode CE (CE1, CE2, CE3), and a second organic layer 210.

A pixel electrode layer including pixel electrodes PXE1, PXE2, and PXE3 and the common electrode CE (CE1, CE2, CE3) may be disposed on the second planarization organic film 180.

Each of the first pixel electrode PXE1, the second pixel electrode PXE2, and the third pixel electrode PXE3 may be connected to a second source connection electrode PCE2 through a connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrode CE may be connected to a second power supply line (VSL in FIG. 4) to which a second driving voltage (VSS in FIG. 3) is applied in a non-display area.

The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) having low surface resistance to lower the resistance of each of the pixel electrodes PXE1, PXE2, and PXE3 and the common electrode CE.

Reflective films RF-P and RF-C may be further included on the pixel electrodes PXE1, PXE2, and PXE3 and the common electrode CE. The reflective film RF-P and RF-C may include a metal material having a high reflectivity, such as aluminum (Al). The thickness of the reflective film RF-P and RF-C may be approximately 0.1 μm. The reflective film RF-P disposed on the pixel electrodes PXE1, PXE2, and PXE3 may be referred to as a first reflective film RF-P, and the reflective film RF-C disposed on the common electrode CE may be referred to as a second reflective film RF-C.

A first organic layer 190 may be disposed on the pixel electrode layer. The first organic layer 190 may include a sloped portion 190-S and an upper portion 190-T extending from the sloped portion 190-S.

A first opening area OP-A may be defined by the sloped portion 190-S. The first opening area OP-A overlaps with an area between the pixel electrodes PXE1, PXE2, and PXE3 and the common electrode CE, and may overlap with at least a portion of the pixel electrodes PXE1, PXE2, and PXE3 and the common electrode CE. Accordingly, at least a portion of the pixel electrodes PXE1, PXE2, and PXE3 and the common electrode CE may be exposed by the first opening area OP-A. The area exposed by the first opening area OP-A may be larger than the area of the light emitting element LE.

The first organic layer 190 may be formed of an organic film, such as an acrylic resin, an epoxy resin, a phenolic resin, a polyamide resin, a polyimide resin, and/or the like.

Referring now to FIG. 8 in addition to FIG. 7, a first bottom connection electrode BBE1 and a second bottom connection electrode BBE2 may be disposed on the first organic layer 190 on the sloped portion 190-S and the upper portion 190-T of the first organic layer 190.

The first bottom connection electrode BBE1 extends from one side of the sloped portion 190-S to the upper surface of the first reflective film RF-P. Therefore, the first bottom connection electrode BBE1 is electrically connected to the first reflective film RF-P. The second bottom connection electrode BBE2 extends from one side of the sloped portion 190-S to the top surface of the second reflective film RF-C. Therefore, the second bottom connection electrode BBE2 is electrically connected to the second reflective film RF-C.

The first bottom connection electrode BBE1 and the second bottom connection electrode BBE2 are spaced (e.g., spaced apart) from each other and are not electrically connected.

The first bottom connection electrode BBE1 and the second bottom connection electrode BBE2 may include molybdenum (Mo), aluminum (Al), chromium (Cr), gold (Au), titanium (Ti), nickel (Ni), neodymium (Nd), and/or copper (Cu). Specifically, each of the first bottom connection electrode BBE1 and the second bottom connection electrode BBE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

A first protective layer INS1 is disposed on the first organic layer 190 and the first opening area OP-A. The first protective layer INS1 covers both the first bottom connection electrode BBE1 and the second bottom connection electrode BBE2.

In one or more embodiments, the upper portion of the first organic layer 190 may be higher than the active layer MQW of the light emitting element LE and lower than the upper portion of the light emitting element LE. However, in one or more other embodiments, the upper portion of the first organic layer 190 may be lower than the active layer MQW of the light emitting element LE.

A reflective layer RF is disposed on the first protective layer INS1 overlapping the sloped portion 190-S.

The reflective layer RF may be a closed loop shape that surrounds the side surface of the light emitting element LE and is spaced (e.g., spaced apart) from the light emitting element LE. The reflective layer RF may reflect light traveling in the side direction from the light emitting element LE and emit light to the top surface of the light emitting element LE. Therefore, because the loss of light from the light emitting element LE may be reduced, the light efficiency of the light emitting element LE may be increased.

When the height of the first organic layer 190 is positioned higher than the active layer MQW of the light emitting element LE, the top portion of the reflective layer RF may be positioned higher than the active layer MQW of the light emitting element LE. The bottom portion of the reflective layer RF may be positioned lower than or equal to the light emitting element LE. The reflective layer RF may include a metal material having a high reflectivity, such as aluminum (Al).

The inclination θ1 of the sloped portion 190-S may be about 120° to 130°.

The inclination θ1 of the sloped portion 190-S may be defined by the first reflective film RF-P and the virtual surface VS1 of the first organic layer 190 that contacts the first reflective film RF-P. Because the reflective layer RF is disposed on the sloped portion 190-S, the reflective layer RF also has the same inclination θ2 as the inclination θ1 of the sloped portion 190-S. Therefore, the inclination θ2 of the reflective layer RF may be about 120° to 130°. The greater the inclination θ2 of the reflective layer RF, the higher the front light emission efficiency.

A second protective layer INS2 is disposed on the first organic layer 190, the first bottom connection electrode BBE1, the second bottom connection electrode BBE2, the first protective layer INS1, and the reflective layer RF. The second protective layer INS2 may be disposed to cover the entire reflective layer RF.

Therefore, the reflective layer RF may be surrounded by the first protective layer INS1 and the second protective layer INS2. The reflective layer RF is electrically isolated from external components.

The first protective layer INS1 and the second protective layer INS2 may be formed of an inorganic film, for example, silicon nitride (SiNₓ), silicon oxide (SiON), silicon oxide (SiOₓ), titanium oxide (TiOₓ), or aluminum oxide (AlOₓ).

A contact hole INS-H penetrating the first protective layer INS1 and the second protective layer INS2 is positioned in an area overlapping the upper portion 190-T of the first organic layer 190. At least a portion of the first bottom connection electrode BBE1 and the second bottom connection electrode BBE2 on the top surface of the upper portion 190-T of the first organic layer 190 is exposed by the contact hole INS-H. The contact hole INS-H may have a polygonal planar shape, such as a circle, an ellipse, or a square.

A second organic layer 210 may be disposed within the first opening area OP-A. The second organic layer 210 temporarily fixes or adheres the upper member (e.g., the light emitting element LE). For example, the second organic layer 210 may be a film for temporarily adhering the upper member (e.g., the light emitting element LE) onto each of the pixel electrodes PXE1, PXE2, and PXE3 and the common electrode CE. To facilitate the temporary adhesion, the thickness of the second organic layer 210 may be greater than the thickness of each of the pixel electrodes PXE1, PXE2, and PXE3 and the common electrode CE, and may be greater than the thickness of the contact electrode CTE. For example, the thickness of the second organic layer 210 may be 1.2 μm but is not limited thereto.

The second organic layer 210 may partially overlap with the reflective layer RF.

The second organic layer 210 may be a photosensitive organic film such as a photoresist. Alternatively, the second organic layer 210 may be formed from an acrylic resin, an epoxy resin, a phenolic resin, a polyamide resin, a polyimide resin, and/or the like.

A plurality of light emitting elements LE may be disposed on the second organic layer 210. In FIGS. 6 and 7, the light emitting element LE is shown as a flip-type micro LED. The flip-type micro LED refers to an LED in which contact electrodes CTE1 and CTE2 are formed on one surface (e.g., the bottom surface) of the light emitting element LE. The light emitting element LE may include a substantially vertical side surface as illustrated in FIG. 7. For example, the light emitting element LE may be patterned through vertical etching and may have a rectangular or square cross-sectional shape in which the width of the top surface and the width of the bottom surface are substantially the same. Each of the plurality of light emitting elements LE may be formed of an inorganic material such as gallium nitride (GaN). The shape of the light emitting element LE may vary depending on the embodiments. For example, the light emitting element LE may have a cross-sectional shape of an inverted taper. For example, the light emitting element LE may have a cross-sectional shape of an inverted trapezoid in which the width of the top surface is wider than the width of the bottom surface.

Each of the plurality of light emitting elements LE may be formed by growing on a semiconductor substrate such as a silicon substrate and/or a sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 by an electrostatic method using an electrostatic head or a stamp method using an elastic polymer material such as PDMS or silicon as a transfer substrate.

As shown in FIG. 7-FIG. 9, the light emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, and a second semiconductor layer SEM2 sequentially disposed along the third direction DR3.

The conductive layer E1 may be disposed on the bottom surface of the first semiconductor layer SEM1. In FIG. 7, the conductive layer E1 is illustrated as covering the entire bottom surface of the first semiconductor layer SEM1, but the present disclosure is not limited thereto. For example, the conductive layer E1 may be disposed on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may be formed of a semiconductor material layer doped with a first conductive dopant such as magnesium (Mg), zinc (Zn), calcium (Ca), strontium (Sr), barium (Ba), etc., for example, gallium nitride (GaN).

In one or more embodiments, the first semiconductor layer SEM1 may have a multilayer structure. For example, the first semiconductor layer SEM1 may include a P-GaN layer and a P+GaN layer. The P+GaN layer may be disposed under the P-GaN layer. The P+GaN layer may be a layer overdoped with the first conductive dopant. The P+GaN layer may be formed with a thickness of several nanometers to several tens of nanometers on the top side to help ohmic formation. The P+GaN is very useful for lowering the operating voltage by improving ohmic characteristics with the upper metal through the tunneling effect.

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

For example, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be disposed on the active layer MQW. The second semiconductor layer SEM2 may be a semiconductor material layer doped with a second conductivity type dopant such as silicon (Si), germanium (Ge), tin (Sn), etc., for example, gallium nitride (GaN).

In one or more embodiments, the second semiconductor layer SEM2 may have a multilayer structure. For example, the second semiconductor layer SEM2 may include an N-GaN layer and an N+GaN layer disposed on the N-GaN layer. The N+GaN layer may be a layer heavily doped with a second conductive dopant. The N+GaN layer may lower electrical resistance and improve current distribution when forming an ohmic electrode, thereby increasing the overall uniformity of light emission of the light emitting element LE.

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The protective film INS may be a film for protecting the bottom surface and the side surface of the light emitting element LE. The protective film INS may be disposed on the bottom surface and the side surface of the conductive layer E1 and the side surface of the semiconductor stack STC. Specifically, the protective film INS may be disposed on the bottom surface and the side surface of the conductive layer E1, the side surface of the first semiconductor layer SEM1, the side surface of the active layer MQW, and the side surface of the second semiconductor layer SEM2.

The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A hole LEH may be formed that penetrates the conductive layer E1, the first semiconductor layer SEM1, and the active layer MQW of the light emitting element LE to expose the second semiconductor layer SEM2. The hole LEH may have a rectangular planar shape, but the present disclosure is not limited thereto. For example, the hole LEH may have a polygonal planar shape such as a circle, an ellipse, or a square.

The first contact electrode CTE1 may be disposed on at least one side surface of the semiconductor stack STC, and at least one side surface and the bottom surface of the conductive layer E1. The first contact electrode CTE1 may be disposed on the bottom surface of the conductive layer E1 exposed without being covered by the protective film INS. Therefore, the first contact electrode CTE1 may be electrically connected to the conductive layer E1.

The second contact electrode CTE2 may be disposed on at least one side of the semiconductor stack STC and at least one side and the bottom surface of the conductive layer E1. At this time, the first contact electrode CTE1 may be disposed on the first side of the semiconductor stack STC and the first side of the conductive layer E1, while the second contact electrode CTE2 may be disposed on the second side of the semiconductor stack STC and the second side of the conductive layer E1.

The second contact electrode CTE2 may be disposed on the protective film INS disposed in the hole LEH and the second semiconductor layer SEM2 exposed without being covered by the protective film INS in the hole LEH. Therefore, the second contact electrode CTE2 may be electrically connected to the second semiconductor layer SEM2 in the hole LEH.

The first contact electrode CTE1 and the second contact electrode CTE2 may be disposed on at least a portion of a side surface of the semiconductor stack STC. From among the side surfaces of the semiconductor stack STC, at least an area adjacent to a top surface of the semiconductor stack STC may be exposed without being covered by the first contact electrode CTE1 and the second contact electrode CTE2. For example, the first contact electrode CTE1 and the second contact electrode CTE2 may be spaced (e.g., spaced apart) from the top surface of the semiconductor stack STC in the third direction DR3.

The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The first upper connection electrode UBE1 connects the first contact electrode CTE1 and the first bottom connection electrode BBE1. For example, the first upper connection electrode UBE1 may be connected to the first bottom connection electrode BBE1 exposed through a contact hole INS-H1 penetrating the protective layer INS1 and INS2. In addition, the first upper connection electrode UBE1 may be disposed on the top surface of the second protective layer INS2 and the first contact electrode CTE1.

The second upper connection electrode UBE2 connects the second contact electrode CTE2 and the second bottom connection electrode BBE2. For example, the second upper connection electrode UBE2 may be connected to the second bottom connection electrode BBE2 exposed through a contact hole INS-H2 penetrating the protective layer INS1 and INS2. Also, the second upper connection electrode UBE2 may be disposed on the top surface of the second protective layer INS2 and the second contact electrode CTE2.

The first upper connection electrode UBE1 and the second upper connection electrode UBE2 may include molybdenum (Mo), aluminum (Al), chromium (Cr), gold (Au), titanium (Ti), nickel (Ni), neodymium (Nd), and/or copper (Cu). Specifically, each of the first upper connection electrode UBE1 and the second upper connection electrode UBE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The third organic layer 211 may be disposed to cover a plurality of light emitting elements LE. Further, the third organic layer 211 may be disposed to cover the first upper connection electrode UBE1 and the second upper connection electrode UBE2.

The third organic layer 211 is a layer for flattening the steps caused by the plurality of light emitting elements LE. When the height of the third organic layer 211 is disposed to cover only a portion of the side surface of each of the plurality of light emitting elements LE, an additional organic film may be disposed on the third organic layer 211. The third organic layer 211 may be formed of an organic film such as an acrylic resin, an epoxy resin, a phenolic resin, a polyamide resin, a polyimide resin, and/or the like.

On the other hand, when the second organic layer 210 is made of a photosensitive organic material such as a photoresist, the second organic layer 210 is soft baked at a first temperature, and then the light emitting element LE is disposed on the second organic layer 210. As shown in FIG. 7, the light emitting element LE is embedded in the second organic layer 210 in a soft-cured state by the pressure applied when the light emitting element LE is disposed on the second organic layer 210. At least a portion of each of the plurality of light emitting elements LE is inserted into the second organic layer 210.

In another embodiment, as shown in FIG. 9, the light emitting elements LE are relatively deeply embedded in the second organic layer 210, and at this time, the first protective layer INS1 may serve as an insertion fixing layer. One side of the first contact electrode CTE1 and the second contact electrode CTE2 of the light emitting elements LE may contact the first protective layer INS1. That is, the light emitting elements LE may be inserted into the second organic layer 210 until they contact the first protective layer INS1.

Referring again to FIGS. 6 and 7, the third organic layer 211 may be disposed to cover the side surfaces of the plurality of light emitting elements LE, the second organic layer 210, and the upper connection electrodes UBE1 and UBE2. For example, the second organic layer 210 and the upper connection electrodes UBE1 and UBE2 may be covered by the third organic layer 211. In one or more embodiments, the top surface of each of the plurality of light emitting elements LE may be exposed without being covered by the third organic layer 211. In another example, the third organic layer 211 may include a plurality of stacked organic films. The third organic layer 211 is a layer for flattening the steps caused by the plurality of light emitting elements LE.

The third organic layer 211 may be formed of an organic film such as an acrylic resin, an epoxy resin, a phenolic resin, a polyamide resin, a polyimide resin, and/or the like.

A light blocking layer BM, a first light conversion layer QDL1, a second light conversion layer QDL2, and a light transmission layer TPL may be disposed on the third organic layer 211. The first light conversion layer QDL1, the second light conversion layer QDL2, and the light transmission layer TPL may be formed by the compartments of the light blocking layer BM. Therefore, the first light conversion layer QDL1 may be disposed on a first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may not overlap the plurality of light emitting elements LE in the third direction DR3.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (e.g., light in the blue wavelength band) incident from the light emitting element LE into first light (e.g., light in the red wavelength band).

The second light conversion layer QDL2 may convert a portion of the third light (e.g., light in the blue wavelength band) incident from the light emitting element LE into second light (e.g., light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (e.g., light in the blue wavelength band) incident from the light emitting element LE into second light (e.g., light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially stacked. A length of the first light blocking layer BM1 in the first direction DR1 or the second direction DR2 may be longer than a length of the second light blocking layer BM2 in the first direction DR1 or a length of the second light blocking layer BM2 in the second direction DR2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black or an organic black pigment.

The first capping layer CAP1 may be disposed on the third organic layer 211 and the light blocking layer BM. The first capping layer CAP1 may be disposed on the side and top surfaces of the light blocking layer BM. That is, the first capping layer CAP1 may be disposed on the side of the first light blocking layer BM1 and the side and top surfaces of the second light blocking layer BM2.

The upper reflective film RF2 may be disposed between the light blocking layer BM and the first light conversion layer QDL1, between the light blocking layer BM and the second light conversion layer QDL2, and between the light blocking layer BM and the light transmission layer TPL. The upper reflective film RF2 may be disposed on the first capping layer CAP1 disposed on the side surface of the first light blocking layer BM1, and the upper surface and the side surface of the second light blocking layer BM2. The upper reflective film RF2 serves to reflect light traveling in the side surface direction from the first light conversion layer QDL1, the second light conversion layer QDL2, and the light transmission layer TPL.

The upper reflective film RF2 may include a highly reflective metal material such as aluminum (Al). The thickness of the upper reflective film RF2 may be approximately 0.1 [symbol] .

Alternatively, the upper reflective film RF2 may include a first layer and a second layer of M (M is an integer of 2 or more) pairs having different refractive indices to serve as Distributed Bragg Reflectors (DBR). In this case, M first layers and M second layers may be disposed alternately. The first layer and the second layer may be formed of an inorganic film, for example, silicon nitride (SiNₓ), silicon oxide (SiON), silicon oxide (SiOₓ), titanium oxide (TiOₓ), and/or aluminum oxide (AlOₓ).

The second capping layer CAP2 may be disposed on the first capping layer CAP1, the upper reflective film RF2, the first light conversion layer QDL1, the second light conversion layer QDL2, and the light transmission layer TPL.

The first capping layer CAP1 and the second capping layer CAP2 may be formed of an inorganic film, for example, silicon nitride (SiNₓ), silicon oxide (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capping layer CAP1 and the second capping layer CAP2.

A fourth organic layer 212 may be disposed on the second capping layer CAP2. A plurality of color filters CF1, CF2, and CF3 may be disposed the fourth organic layer 212. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) that has been converted by the first light conversion layer QDL1 from among the third light (e.g., light in the blue wavelength band) emitted from the light emitting element LE and absorb or block the third light (e.g., light in the blue wavelength band) that has not been converted by the first light conversion layer QDL1. Accordingly, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) that has been converted by the second light conversion layer QDL2 from among the third light (e.g., light in the blue wavelength band) emitted from the light emitting element LE and absorb or block the third light (e.g., light in the blue wavelength band) that has not been converted by the second light conversion layer QDL2. Accordingly, the second sub-pixel SPX2 may emit the second light (e.g., light in the green wavelength band).

The third color filter CF3 disposed in the third sub-pixel SPX3 may transmit the third light (e.g., light in the blue wavelength band). Therefore, the third color filter CF3 may transmit the third light (e.g., light in the blue wavelength band) emitted from the light emitting element LE passing through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the light blocking layer BM in the third direction DR3.

A fifth organic film 213 for planarization may be disposed on the plurality of color filters CF1, CF2, and CF3.

The fourth organic layer 212 and the fifth organic film 213 may be formed from an acrylic resin, an epoxy resin, a phenolic resin, a polyamide resin, a polyimide resin, and/or the like.

FIG. 10 is a cross-sectional view illustrating another example of an area A of FIG. 6 in detail.

The embodiment of FIG. 10 is different from the embodiment of FIG. 7 in that the first bottom connection electrode BBE1 and the second bottom connection electrode BBE2 are omitted, and a contact hole INS-H is formed deeply so that the upper connection electrodes UBE1 and UBE2 and the reflective films RF-P and RF-C are in direct contact. In FIG. 10, the overlapping descriptions with the embodiment described with reference to FIGS. 6 and 7 will not be repeated, and the differences from the embodiment of FIG. 7 will be mainly described.

Referring to FIG. 10, the reflective films RF-P and RF-C may be further included on the pixel electrodes PXE1, PXE2, and PXE3 and the common electrode CE.

The reflective film RF-P disposed on the pixel electrodes PXE1, PXE2, and PXE3 may be referred to as a first reflective film RF-P, and the reflective film RF-C disposed on the common electrode CE may be referred to as a second reflective film RF-C.

A first organic layer 190 may be disposed on the pixel electrode layer. The first organic layer 190 may include a sloped portion 190-S and an upper portion 190-T extending from the sloped portion 190-S.

A first opening area OP-A may be defined by the sloped portion 190-S. The first opening area OP-A overlaps with an area between the pixel electrodes PXE1, PXE2, and PXE3 and the common electrode CE, and may overlap with at least a portion of the pixel electrodes PXE1, PXE2, and PXE3 and the common electrode CE. Accordingly, at least a portion of the pixel electrodes PXE1, PXE2, and PXE3 and the common electrode CE may be exposed by the first opening area OP-A. The area exposed by the first opening area OP-A may be larger than the area of the light emitting element LE.

A first protective layer INS1 is disposed on the first organic layer 190 and the first opening area OP-A.

A reflective layer RF is disposed on the first protective layer INS1 overlapping the sloped portion 190-S.

The reflective layer RF is spaced (e.g., spaced apart) from the light emitting element LE and may be around (e.g., may surround) the side of the light emitting element LE. The reflective layer RF may reflect light traveling in the side direction from the light emitting element LE to increase light emission efficiency. Because the height of the first organic layer 190 is higher than the active layer MQW of the light emitting element LE, the upper end of the reflective layer RF may be positioned higher than the active layer MQW of the light emitting element LE. The lower end of the reflective layer RF may be positioned lower than or equal to the light emitting element LE. The reflective layer RF may include a highly reflective metal material such as aluminum (Al).

A second protective layer INS2 is disposed on the first organic layer 190 and the reflective layer RF. The second protective layer INS2 may be disposed to cover the entire reflective layer RF.

Therefore, the reflective layer RF may be surrounded by the first protective layer INS1 and the second protective layer INS2. The reflective layer RF is electrically isolated from external components.

A contact hole INS-H1 penetrating the first protective layer INS1, the second protective layer INS2, and the first organic layer 190 is positioned in an area overlapping the upper portion 190-T of the first organic layer 190. At least a portion of the reflective films RF-P is exposed by the contact hole INS-H1. The contact hole INS-H1 may have a polygonal planar shape such as a circle, an ellipse, or a square.

The first upper connection electrode UBE1 connects the first contact electrode CTE1 and the first reflective film RF-P. For example, the first upper connection electrode UBE1 may be connected to the first reflective film RF-P exposed through a contact hole INS-H1 penetrating the protective layers INS1 and INS2 and the first organic layer 190. Further, the first upper connection electrode UBE1 may be disposed on the top surface of the second protective layer INS2 and the first contact electrode CTE1.

The second upper connection electrode UBE2 connects the second contact electrode CTE2 and the second reflective film RF-C. For example, the second upper connection electrode UBE2 may be connected to the second reflective film RF-C exposed through a contact hole INS-H2 penetrating the protective layers INS1 and INS2 and the first organic layer 190. Further, the second upper connection electrode UBE2 may be disposed on the top surface of the second protective layer INS2 and the second contact electrode CTE2.

The third organic layer 211 may be disposed to cover a plurality of light emitting elements LE. Further, the third organic layer 211 may be disposed to cover the first upper connection electrode UBE1 and the second upper connection electrode UBE2. The third organic layer 211 may fill the inside of the contact holes INS-H1 and INS-H2.

FIG. 11 is an image illustrating a cross-sectional view of a display panel according to one or more embodiments.

Referring to FIG. 11, a distance D2 from the center of the first light emitting element LE1 to the center of the neighboring second light emitting element LE2 may be about 26 μm, and a distance D1 between the first light emitting element LE1 and the second light emitting element LE2 may be about 5.5 μm.

Because the distance between the light emitting elements LE1 and LE2 is very narrow, considering that the alignment margin of the light emitting elements LE1 and LE2 is about 2 μm, the space in which the first organic layer 190 may be formed is about 3 μm. Because the space for forming the first organic layer 190 is very narrow, the shape of the first organic layer 190 may be formed irregularly. Accordingly, the reflective layer located on the inclined surface of the organic layer is often formed abnormally. This problem may be more severe in high-resolution display devices.

Therefore, in one or more embodiments, the first organic layer 190 is formed, and a reflective layer RF is formed on an inclined surface of the first organic layer 190. Then, by positioning the light emitting element LE between the first organic layers 190, the first organic layer 190 and the reflective layer RF may be formed normally. This manufacturing method will be described in detail with reference to FIGS. 14-24.

FIG. 12 is a layout diagram illustrating pixels of a display area according to one or more embodiments.

The embodiment of FIG. 12 differs from the embodiment of FIG. 5 in that the light emitting elements LE are disposed on the pixel electrodes PXE1, PXE2, and PXE3 in each of the first sub-pixel SPX1, the second sub-pixel SPX2, and the third sub-pixel SPX3. In FIG. 12, descriptions that overlap with the embodiment of FIG. 5 will be omitted, and differences from the embodiment of FIG. 5 will be mainly described.

Referring to FIG. 12, the first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer TPL.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. For example, the area of the sub-pixel may be larger as the light conversion efficiency is lower.

For example, as shown in FIG. 12, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Further, because the light transmission layer TPL directly transmits the light of the light emitting element LE, while the first light conversion layer QDL1 must convert the light, the area of the first pixel electrode PXE1 may be larger than the area of the third pixel electrode PXE3.

Each of the pixel electrodes PXE1, PXE2, and PXE3 may be electrically connected to at least one transistor through pixel connection holes CT1, CT2, and CT3. For example, each of the pixel electrodes PXE1, PXE2, and PXE3 may be electrically connected to the first electrode of the fourth transistor (ST4 in FIG. 4) of the corresponding sub-pixel and the second electrode of the sixth transistor (ST6 in FIG. 4).

The plurality of light emitting elements LE may be disposed on each of the pixel electrodes PXE1, PXE2, and PXE3. The same number of light emitting elements LE may be disposed on each of the pixel electrodes PXE1, PXE2, and PXE3. For example, two light emitting elements LE may be disposed on each of the pixel electrodes PXE1, PXE2, and PXE3. The plurality of light emitting elements LE may emit light of a third color, that is, light in a blue wavelength band, but the present disclosure is not limited thereto.

Each of the plurality of light emitting elements LE may have a circular planar shape, but the present disclosure is not limited thereto. For example, each of the plurality of light emitting elements LE may have a rectangular planar shape.

The first light conversion layer QDL1 may completely overlap with the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit it. For example, the first light conversion layer QDL1 may convert or shift third light emitted from the plurality of light emitting elements LE of the first sub-pixel SPX1 into first light.

The second light conversion layer QDL2 may completely overlap with the second pixel electrode PXE2 and the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into the second light.

The light transmission layer TPL may completely overlap the third pixel electrode PXE3 and the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

FIG. 13 a cross-sectional view illustrating an example of a cross-section of a display panel corresponding to the line I2-I2′ of FIG. 12. FIG. 14 is a cross-sectional view illustrating an example of an area B of FIG. 13 in detail.

The embodiments of FIGS. 13 and 14 differ from the embodiments of FIGS. 6 and 7 in that each of the plurality of light emitting elements LE is a vertical type micro LED extending in a third direction DR3. The vertical type micro LED refers to an LED having a structure in which a first semiconductor layer SEM1, an active layer MQW, and a second semiconductor layer SEM2 are sequentially disposed along the third direction DR3, which is a vertical direction. Each of the plurality of light emitting elements LE may have a cross-sectional shape of a reverse taper. For example, each of the plurality of light emitting elements LE may have a trapezoidal cross-sectional shape in which the width of the top surface is wider than the width of the bottom surface. The shape of the light emitting element LE may vary depending on the embodiments. For example, each of the plurality of light emitting elements LE may include a substantially vertical side surface. The light emitting element LE may be patterned through vertical etching and may have a rectangular or square cross-sectional shape in which the width of the top surface and the width of the bottom surface are substantially the same.

In the embodiments of FIGS. 13 and 14, descriptions that overlap with those of the embodiments of FIGS. 6 and 7 are omitted.

Referring to FIGS. 13 and 14, pixel electrodes PXE1, PXE2, and PXE3 may be disposed on the second planarization organic film 180.

A first reflective film RF-P may be disposed on each of the pixel electrodes PXE1, PXE2, and PXE3.

The first reflective film RF-P may include a metal material having a high reflectivity, such as aluminum (Al). The thickness of the reflective film RF-P may be approximately 0.1 μm.

A first organic layer 190 may be disposed on the pixel electrodes PXE1, PXE2, and PXE3. The first organic layer 190 may include a sloped portion 190-S and an upper portion 190-T (e.g., see FIG. 8) extending from the sloped portion 190-S.

A first opening area OP-A (e.g., see FIG. 7) may be defined by the sloped portion 190-S. The first opening area OP-A may overlap with the pixel electrodes PXE1, PXE2, and PXE3. Accordingly, at least a portion of the pixel electrodes PXE1, PXE2, and PXE3 and the first reflective film RF-P on the pixel electrodes PXE1, PXE2, and PXE3 may be exposed by the first opening area OP-A. The area exposed by the first opening area OP-A may be larger than the area of the light emitting element LE.

A first bottom connection electrode BBE1 and a second bottom connection electrode BBE2 may be disposed on the first organic layer 190 on the sloped portion 190-S and the upper portion 190-T (e.g., see FIG. 8) of the first organic layer 190.

The first bottom connection electrode BBE1 and the second bottom connection electrode BBE2 extend from one surface of the sloped portion 190-S to the top surface of the first reflective film RF-P. Therefore, the first bottom connection electrode BBE1 and the second bottom connection electrode BBE2 are electrically connected to the first reflective film RF-P.

A first protective layer INS1 is disposed on the first organic layer 190 and the first opening area OP-A. The first protective layer INS1 covers both the first bottom connection electrode BBE1 and the second bottom connection electrode BBE2.

The upper portion of the first organic layer 190 may be higher than the active layer MQW of the light emitting element LE and lower than the upper portion of the light emitting element LE.

A reflective layer RF is disposed on the first protective layer INS1 overlapping the sloped portion 190-S.

The reflective layer RF may be a closed loop shape that is around (e.g., surrounds) the side surface of the light emitting element LE and is spaced (e.g., spaced apart) from the light emitting element LE. The reflective layer RF may reflect light traveling in the side direction from the light emitting element LE and emit light to the top surface of the light emitting element LE. Therefore, because the loss of light from the light emitting element LE may be reduced, the light emission efficiency of the light emitting element LE may be increased.

When the height of the first organic layer 190 is positioned higher than the active layer MQW of the light emitting element LE, the top portion of the reflective layer RF may be positioned higher than the active layer MQW of the light emitting element LE. The bottom portion of the reflective layer RF may be positioned lower than or equal to the light emitting element LE. The reflective layer RF may include a metal material having a high reflectivity, such as aluminum (Al).

The inclination θ1 (e.g., see FIG. 8) of the sloped portion 190-S may be about 120° to 130°. The inclination θ1 of the sloped portion 190-S may be defined by the first reflective film RF-P and the virtual surface VS1 of the first organic layer 190 that contacts the first reflective film RF-P (e.g., see FIG. 8). Because the reflective layer RF is disposed on the sloped portion 190-S, the reflective layer RF also has the same inclination θ2 as the inclination θ1 of the sloped portion 190-S (e.g., see FIG. 8). Therefore, the inclination θ2 of the reflective layer RF may be about 120° to 130°. The greater the inclination θ2 of the reflective layer RF, the higher the front light emission efficiency.

A second protective layer INS2 is disposed on the first organic layer 190, the first bottom connection electrode BBE1, the second bottom connection electrode BBE2, the first protective layer INS1, and the reflective layer RF. The second protective layer INS2 may be disposed to cover the entire reflective layer RF.

Therefore, the reflective layer RF may be surrounded by the first protective layer INS1 and the second protective layer INS2. The reflective layer RF is electrically isolated from external components.

The first protective layer INS1 and the second protective layer INS2 may be formed of an inorganic film, for example, silicon nitride (SiNₓ), silicon oxide (SiON), silicon oxide (SiOₓ), titanium oxide (TiOₓ), and/or aluminum oxide (AlOₓ).

A contact hole INS-H penetrating the first protective layer INS1 and the second protective layer INS2 is positioned in an area overlapping the upper portion 190-T of the first organic layer 190 (e.g., see FIG. 8). At least a portion of the first bottom connection electrode BBE1 and the second bottom connection electrode BBE2 on the top surface of the upper portion 190-T of the first organic layer 190 is exposed by the contact hole INS-H (e.g., see FIG. 8). The contact hole INS-H may have a polygonal planar shape, such as a circle, an ellipse, or a square.

A second organic layer 210 may be disposed within the first opening area OP-A (e.g., see FIG. 7). The second organic layer 210 temporarily fixes or adheres the upper member (e.g., the light emitting element LE). For example, the second organic layer 210 may be a film for temporarily adhering the upper member (e.g., the light emitting element LE) onto each of the pixel electrodes PXE1, PXE2, and PXE3. To facilitate the temporary adhesion, the thickness of the second organic layer 210 may be greater than the thickness of each of the pixel electrodes PXE1, PXE2, and PXE3 and may be greater than the thickness of the contact electrode CTE. For example, the thickness of the second organic layer 210 may be 1.2 μm but is not limited thereto.

The plurality of light emitting elements LE may be disposed on the second organic layer 210.

Each of the plurality of light emitting elements LE may have a length in the first direction DR1, a length in the second direction DR2, and a length in the third direction DR3 of several to several hundred μm, respectively. For example, each of the plurality of light emitting elements LE may have a length in the first direction DR1, a length in the second direction DR2, and a length in the third direction DR3 of approximately 100 μm or less, respectively.

The light emitting element LE may include a conductive layer E1, a semiconductor stack STC, a contact electrode CTE, and a protective film INS. The semiconductor stack STC may include a first semiconductor layer SEM1, an active layer MQW, and a second semiconductor layer SEM2 that are sequentially disposed along the third direction DR3.

A light extraction patterns LEP may be formed on a top surface of the semiconductor stack STC. For example, light extraction patterns LEP may be formed on the top surface of the second semiconductor layer SEM2.

The light extraction patterns LEP may be patterns for increasing the efficiency of light emitted from the top surface of the light emitting element LE. The light extraction patterns LEP may be concave patterns formed in a hemisphere or a semi-ellipse.

The protective film INS may be disposed on the side surface of the first semiconductor layer SEM1, the side surface of the active layer MQW, and the side surface of the second semiconductor layer SEM2. The protective film INS may be a film for protecting the side surface of the light emitting element LE. The protective film INS may be formed of an inorganic film, for example, silicon nitride (SiNₓ), silicon oxide (SiON), silicon oxide (SiOₓ), titanium oxide (TiOₓ), and/or aluminum oxide (AlOₓ).

The contact electrode CTE may be disposed on the outside of the light emitting element LE rather than the protective film INS. The contact electrode CTE may be connected to the exposed conductive layer E1 that is not covered by the protective film INS.

When the contact electrode CTE is formed of a metal with high reflectivity, light emitted from the active layer MQW of the light emitting element LE and traveling in the lateral direction of the light emitting element LE may be reflected by the contact electrode CTE and emitted to the top surface of the light emitting element LE. Therefore, because the loss of light from the light emitting element LE may be reduced, the light emission efficiency of the light emitting element LE may be increased.

The contact electrode CTE may include molybdenum (Mo), aluminum (Al), chromium (Cr), gold (Au), titanium (Ti), nickel (Ni), neodymium (Nd), and/or copper (Cu). For example, the contact electrode CTE may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The first upper connection electrode UBE1 connects the contact electrode CTE and the first bottom connection electrode BBE1. For example, the first upper connection electrode UBE1 may be connected to the first bottom connection electrode BBE1 exposed through a contact hole INS-H1 penetrating the protective layer INS1 and INS2. In addition, the first upper connection electrode UBE1 may be disposed on the top surface of the second protective layer INS2 and the contact electrode CTE.

The second upper connection electrode UBE2 connects the contact electrode CTE and the second bottom connection electrode BBE2. For example, the second upper connection electrode UBE2 may be connected to the second bottom connection electrode BBE2 exposed through a contact hole INS-H2 penetrating the protective layer INS1 and INS2. Also, the second upper connection electrode UBE2 may be disposed on the top surface of the second protective layer INS2 and the contact electrode CTE.

The third organic layer 211 may be disposed to cover a portion of the side surface of the plurality of light emitting elements LE. Further, the third organic layer 211 may be disposed to cover the first upper connection electrode UBE1 and the second upper connection electrode UBE2. The third organic layer 211 does not cover the top surface of each of the plurality of light emitting elements LE. Therefore, the top surface of each of the plurality of light emitting elements LE may be exposed without being covered by the third organic layer 211.

The third organic layer 211 is a layer for flattening the steps caused by the plurality of light emitting elements LE.

The common electrode CE may be disposed on the top surface of each of the plurality of light emitting elements LE and the top surface of the third organic layer 211. The common electrode CE may be a common layer formed commonly on the first sub-pixel SPX1, the second sub-pixel SPX2, and the third sub-pixel SPX3. The common electrode CE may be made of a transparent conductive material (TCO) such as indium tin oxide (ITO) and/or indium zinc oxide (IZO) that may transmit light.

The pixel electrodes PXE1, PXE2, and PXE3 may be referred to as an anode electrode or a first electrode, and the common electrode CE may be referred to as a cathode electrode or a second electrode.

A device capping layer CAP may be disposed on the common electrode CE.

A light blocking layer BM, a first light conversion layer QDL1, a second light conversion layer QDL2, and a light transmission layer TPL, and/or other additional layers may be disposed on the device capping layer CAP.

FIG. 15 is a flow chart illustrating a method for manufacturing a display device according to one or more embodiments.

FIG. 16-FIG. 25 are example drawings to illustrate a method for manufacturing a display device according to one or more embodiments.

Hereinafter, a method for manufacturing a display device according to one or more embodiments will be described in detail by connecting FIG. 15 with FIG. 16-FIG. 25. The method for manufacturing a display device described with reference to FIG. 16-FIG. 25 may be a display device including a light emitting element and a display panel described with reference to FIG. 5-FIG. 7. FIG. 16-FIG. 25 are cross-sectional views of a display panel corresponding to FIG. 7. In some drawings, a plan view corresponding to the cross-sectional view is also illustrated for convenience of explanation.

First, a pixel electrode PXE, a common electrode CE, and reflective films RF-P and RF-C are formed on a circuit board 110. (S110 in FIG. 15).

Referring to FIG. 16, a conductive material layer and a reflective material layer are entirely deposited on the circuit board 110, a mask pattern is formed on the conductive material layer, and the conductive material layer not covered by the mask pattern is etched. Then, the mask pattern may be removed by an ashing process. In this way, the pixel electrode PXE, the common electrode CE, and the reflective films RF-P and RF-C may be formed on the circuit board 110. Here, the circuit board 110 may include a thin-film transistor layer TFTL of FIG. 6.

Second, a first organic layer 190 having a first opening area OP-A is formed. (S120 in FIG. 15)

Referring to FIG. 17, the first organic layer 190 having a first opening area OP-A may be formed by an inkjet process using an organic material but is not limited thereto. At least a portion of the first reflective film RF-P and the second reflective film RF-C may be exposed by the first opening area OP-A.

Third, the bottom connection electrodes BBE1 and BBE2, the first protective layer INS1, the reflective layer RF, and the second protective layer INS2 are formed. (S130 in FIG. 15)

Referring to FIG. 18, a conductive material layer is deposited on the entire surface of the circuit board 110 and patterned using a mask to form the first bottom connection electrode BBE1 and the second bottom connection electrode BBE2. The first bottom connection electrode BBE1 is disposed on the first organic layer 190 and the first reflective film RF-P and overlaps the pixel electrode PXE. The second bottom connection electrode BBE2 is disposed on the first organic layer 190 and the second reflective film RF-C and overlaps the common electrode CE. The first bottom connection electrode BBE1 and the second bottom connection electrode BBE2 are spaced (e.g., spaced apart) from each other.

Referring to FIG. 19, a protective material layer is deposited on the entire surface of the circuit board 110 to form a first protective layer INS1.

Then, referring to FIG. 20, a reflective layer RF is formed to overlap the sloped portion 190-S of the first organic layer 190.

After the reflective material layer is deposited on the entire circuit board, the reflective layer RF is formed by patterning using a mask.

Referring to FIG. 21, a second protective layer INS2 may be formed to cover the reflective layer RF. The reflective layer RF may be surrounded by the first protective layer INS1 and the second protective layer INS2.

Referring to FIG. 22, a contact hole INS-H is formed to expose the bottom connection electrode BBE1 and BBE2 by penetrating the second protective layer INS2 and the first protective layer INS1 overlapping the sloped portion 190-S.

Fourth, a second organic layer 210 is formed and a light emitting element LE is disposed on the second organic layer 210. (S140 in FIG. 15)

The light emitting elements LE may be grown on a semiconductor substrate. The semiconductor substrate may be a silicon wafer substrate or a sapphire substrate.

A plurality of semiconductor layers may be formed on the semiconductor substrate through an epitaxial growth process. As the epitaxial growth process, electron beam deposition, physical vapor deposition (PVD), chemical vapor deposition (CVD), plasma laser deposition (PLD), dual-type thermal evaporation, sputtering, metal organic chemical vapor deposition (MOCVD), and/or the like may be used. In one or more embodiments, a metal-organic chemical vapor deposition (MOCVD) method may be used, but the present disclosure is not limited thereto. The plurality of semiconductor layers may include a first semiconductor layer SEM1, an active layer MQW, and a second semiconductor layer SEM2.

After forming the semiconductor layer, a conductive layer and a contact electrode may be formed on the semiconductor layer.

In FIG. 23, a second organic layer 210 is formed in the first opening area OP-A defined by the first organic layer 190. Thereafter, the light emitting elements LE may be transferred onto the second organic layer 210.

At this time, the light emitting elements LE may be temporarily fixed by being embedded in the second organic layer 210. The first contact electrode CTE1 and the second contact electrode CTE2 of each of the light emitting elements LE are shown as being disposed on the second organic layer 210, but the present disclosure is not limited thereto. For example, the second organic layer 210 may be disposed on a portion of the bottom surface and side surface of the first contact electrode CTE1 of each of the light emitting elements LE and a portion of the bottom surface and side surface of the second contact electrode CTE2. Alternatively, the second organic layer 210 may be disposed on the side surfaces of the conductive layer E1 of each of the light emitting elements LE. Alternatively, the second organic layer 210 may be disposed on the side surfaces of the first semiconductor layer SEM1, the side surfaces of the active layer MQW, and the side surfaces of the second semiconductor layer SEM2 of each of the light emitting elements LE. In this case, the second organic layer 210 may be disposed on a portion of each of the side surfaces of the second semiconductor layer SEM2.

When the fluidity of the organic layer 210 is small or the second organic layer 210 is hard, the depth at which the light emitting element LE is inserted or embedded in the second organic layer 210 may be very small, or the light emitting element LE may be disposed on the second organic layer 210 without being inserted or embedded in the second organic layer 210.

When the second organic layer 210 is a photosensitive organic film such as a photoresist, after the second organic layer 210 is soft baked at a first temperature, at least a portion of each of the plurality of light emitting elements LE is inserted into the second organic layer 210. Then, the second organic layer 210 may be completely hardened at a second temperature higher than the first temperature. The first temperature may be approximately 100 degrees, and the second temperature may be approximately 230 degrees, but the present disclosure is not limited thereto.

Furthermore, the process of completely hardening the second organic layer 210 at the second temperature may be approximately done in 30 minutes.

Fifth, upper connection electrodes UBE1 and UBE2 are formed. (S150 in FIG. 15)

Referring to FIG. 24, first upper connection electrodes UBE1 for connecting the first contact electrode CTE1 of the light emitting element LE and the pixel electrode PXE disposed on the second organic layer 210 and second upper connection electrodes UBE2 for connecting the second contact electrode CTE2 and the common electrode PXE are formed.

For example, the first upper connection electrode UBE1 covers the first contact electrode CTE1 of the light emitting element LE and extends along the second protective layer INS2 to be connected to the first bottom connection electrode BBE1 exposed through the contact hole INS-H. The second upper connection electrode UBE2 covers the second contact electrode CTE2 of the light emitting element LE and extends along the second protective layer INS2 to be connected to the second bottom connection electrode BBE2 exposed through the contact hole INS-H. Accordingly, the first contact electrode CTE1 of the light emitting element LE and the pixel electrode PXE are connected, and the second contact electrode CTE2 and the common electrode CE are electrically connected.

Sixth, a third organic layer 211 is formed. (S160 in FIG. 15) Referring to FIG. 25, a third organic layer 211 is formed to fix the light emitting elements LE and flatten the step caused by the light emitting elements LE.

Then, as shown in FIG. 6, a light blocking layer, a wavelength conversion layer, a light transmission layer, and a color filter layer are sequentially formed.

FIG. 26 is an example view of a smart watch including a display device according to one or more embodiments.

Referring to FIG. 26, a display device 10_1 according to one or more embodiments may be applied to a smart watch 1000_1 which is one of smart devices.

FIGS. 27 and 28 are example views of a virtual reality (VR) device including a display device according to one or more embodiments.

Referring to FIGS. 27 and 28, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 27 and 28, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 29 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 29 is an example view of a VR device including a display device according to one or more embodiments. FIG. 29 illustrates a VR device 1000_3 to which a display device 10_4 according to one or more embodiments has been applied.

Referring to FIG. 29, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 29, a case where the VR device 1000_3 is a glasses-type display device including the eyeglass frame legs 30a and 30b is illustrated as an example. That is, the VR device 1000_3 according to the embodiment is not limited to the one illustrated in FIG. 29 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 29, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

FIG. 30 is an example view illustrating a vehicle instrument cluster and center fascia including display devices according to one or more embodiments. FIG. 30 illustrates a vehicle to which display devices 10_a through 10_e according to one or more embodiments have been applied.

Referring to FIG. 30, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

FIG. 31 is an example view of a transparent display device including a display device according to one or more embodiments.

Referring to FIG. 31, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode and a common electrode on the substrate;
a first organic layer on the pixel electrode and the common electrode and having a first opening area;
a first bottom connection electrode on the first organic layer and electrically connected to the pixel electrode and a second bottom connection electrode on the first organic layer and electrically connected to the common electrode;
a first protective layer covering the first bottom connection electrode and the second bottom connection electrode;
a reflective layer on the first protective layer and overlapping a sloped surface of the first organic layer;
a second protective layer covering the reflective layer;
a second organic layer on the first opening area;
a light emitting element on the second organic layer and comprising a semiconductor stack, a first contact electrode, and a second contact electrode; and
a first upper connection electrode connecting the first contact electrode of the light emitting element and the first bottom connection electrode, and a second upper connection electrode connecting the second contact electrode and the second bottom connection electrode.

2. The display device of claim 1, wherein the reflective layer is around the light emitting element.

3. The display device of claim 2, wherein one end of the reflective layer is lower than a lower portion of the light emitting element.

4. The display device of claim 1, wherein a portion of the reflective layer overlaps the second organic layer.

5. The display device of claim 1, wherein an upper portion of the reflective layer is located higher than an active layer of the light emitting element.

6. The display device of claim 1, further comprising a first reflective film on the pixel electrode and a second reflective film on the common electrode.

7. The display device of claim 6, wherein the first bottom connection electrode extends from the first organic layer to a top surface of the first reflective film, and
wherein the second bottom connection electrode extends from the first organic layer to a top surface of the second reflective film.

8. The display device of claim 6, wherein the first protective layer and the second protective layer have a first contact hole exposing the first bottom connection electrode on a top surface of the first organic layer and a second contact hole exposing the second bottom connection electrode on the top surface of the first organic layer,
wherein the first upper connection electrode contacts the first bottom connection electrode through the first contact hole, and
wherein the second upper connection electrode contacts the second bottom connection electrode through the second contact hole.

9. The display device of claim 1, wherein the light emitting element further comprises:
a conductive layer between the second organic layer and the semiconductor stack; and
a protective film on one surface and side surfaces of the conductive layer and side surfaces of the semiconductor stack,
wherein the first contact electrode is on the protective film and is connected to the conductive layer that is exposed and not covered by the protective film, and wherein the second contact electrode is on the protective film and is in a hole penetrating the conductive layer and a portion of the semiconductor stack.

10. The display device of claim 9, wherein the semiconductor stack comprises a first semiconductor layer, an active layer, and a second semiconductor layer that are sequentially stacked, and
wherein the first contact electrode and the second contact electrode are on an entire side surface of the conductive layer and the first semiconductor layer and an entire side surface of the active layer and are on a portion of a side surface of the second semiconductor layer.

11. The display device of claim 10, wherein the first contact electrode and the second contact electrode are in contact with the first protective layer.

12. A display device comprising:
a substrate;
a pixel electrode and a common electrode on the substrate;
a first reflective film on the pixel electrode and a second reflective film on the common electrode;
a first organic layer on the pixel electrode and the common electrode and having a first opening area;
a first protective layer on the first organic layer;
a reflective layer on the first protective layer and overlapping a sloped surface of the first organic layer;
a second protective layer covering the reflective layer;
a second organic layer on the first opening area;
a light emitting element on the second organic layer and comprising a semiconductor stack, a first contact electrode, and a second contact electrode; and
a first upper connection electrode connecting the first contact electrode of the light emitting element and the pixel electrode, and a second upper connection electrode connecting the second contact electrode and the common electrode,
wherein a first contact hole penetrates through the first protective layer, the second protective layer, and the first organic layer to the first reflective film on a top surface of the pixel electrode, and a second contact hole penetrates through the first protective layer, the second protective layer, and the first organic layer to the second reflective film on a top surface of the common electrode,
wherein the first upper connection electrode contacts the first reflective film through the first contact hole, and the second upper connection electrode contacts the second reflective film through the second contact hole.

13. An electronic device comprising:
a display device configured to display an image,
wherein the display device comprises:
a substrate;
a pixel electrode on the substrate;
a first organic layer on the pixel electrode and having a first opening area;
a first bottom connection electrode and a second bottom connection electrode on the first organic layer and electrically connected to the pixel electrode;
a first protective layer covering the first bottom connection electrode and the second bottom connection electrode;
a reflective layer on the first protective layer and overlapping an inclined surface of the first organic layer;
a second protective layer covering the reflective layer;
a second organic layer on the first opening area;
a light emitting element on the second organic layer and comprising a contact electrode;
a first upper connection electrode and a second upper connection electrode connecting the contact electrode of the light emitting element and the first bottom connection electrode and the second bottom connection electrode; and
a common electrode on the light emitting element.

14. The electronic device of claim 13, further comprising a reflective film on the pixel electrode.

15. The electronic device of claim 14, wherein the first bottom connection electrode and the second bottom connection electrode extend from the first organic layer to a top surface of the reflective film.

16. The electronic device of claim 15, wherein the first protective layer and the second protective layer have a contact hole exposing the first bottom connection electrode on a top surface of the first organic layer,
wherein the first upper connection electrode contacts the first bottom connection electrode through the contact hole.

17. The electronic device of claim 13, wherein the reflective layer is around the light emitting element.

18. The electronic device of claim 17, wherein one end of the reflective layer is lower than a lower portion of the light emitting element.

19. The electronic device of claim 13, wherein a portion of the reflective layer overlaps the second organic layer.

20. The electronic device of claim 13, wherein an upper portion of the reflective layer is located higher than an active layer of the light emitting element.
